(19) United States
(12) Patent Application Publication
(10) Pub. No.: US 2024/0263887 A1
(43) Pub. Date: Aug. 8, 2024

(54) Boiling Cooler

(71) Applicant: Sumitomo Precision Products Co., Ltd., Amagasaki-shi (JP)

(72) Inventors: Akihiro TANABE, Amagasaki-shi (JP); Kiyoaki Yamanaka, Amagasaki-shi (JP); Kenji Ando, Amagasaki-shi (JP)

(21) Appl. No.: 18/605,961

(22) Filed: Mar. 15, 2024

Related U.S. Application Data
(63) Continuation of application No. PCT/JP23/34557, filed on Sep. 15, 2022.

(30) Foreign Application Priority Data
Sep. 17, 2021 (JP) 2021-152161

(51) Int. Cl. F28D 15/02; F28D 9/00

(52) U.S. Cl. CPC F28D 15/0266; F28D 9/0062

(57) ABSTRACT

A boiling cooler includes a boiling part including an accommodation space to accommodate a refrigerant, a refrigerant gas outlet, and a refrigerant liquid inlet, and a condensing part including a refrigerant passage and an external passage. The boiling part includes a first wall to which a heating element is mounted, a second wall facing the first wall via the accommodation space and adjacent to the external passage, and a heat conductive portion to connect the first wall to the second wall through the accommodation space.

### CROSS-REFERENCE TO RELATED APPLICATION

This application is a continuation of PCT application PCT/JP2022/034557, filed on Sep. 15, 2022, claiming a priority of Japanese Patent Application No. 2021-152161 filed on Sep. 17, 2021, the disclosure of which is incorporated herein.

### BACKGROUND OF THE INVENTION

### Field of the Invention

The present invention relates to a boiling cooler, and more particularly, it relates to a boiling cooler that circulates a refrigerant between a boiling part that boils the refrigerant and a condensing part that condenses the vaporized refrigerant.

### Description of the Background Art

Conventionally, a boiling cooler that circulates a refrigerant between a boiling part and a condensing part is known. Such a boiling cooler is disclosed in Japanese Patent Laid-Open No. 8-204075 and Japanese Patent Laid-Open No. 2005-101190, for example.

Japanese Patent Laid-Open No. 8-204075 discloses an element cooler including an evaporation part (boiling part) including a hollow faceplate to which an element (heating element) is mounted, and a condensing part having a refrigerant passage that communicates with an upper end opening of the evaporation part. The condensing part has an air passage to cool a refrigerant gas in the refrigerant passage. In the element cooler, a cycle is repeated in which the element mounted to the evaporation part is cooled by the vaporization of the refrigerant, and the vaporized refrigerant gas is cooled by air in the upper condensing part, becomes liquefied, and returns to the evaporation part.

Japanese Patent Laid-Open No. 2005-101190 discloses a boiling cooler including a plate tube in which a first refrigerant passage extending in an upward-downward direction is formed, tubes extending in the upward-downward direction parallel to the first refrigerant passage, a first header tank that allows the upper end of the plate tube to communicate with the upper ends of the tubes, and a second header tank that allows the lower end of the plate tube to communicate with the lower ends of the tubes. A liquid-phase refrigerant present in the first refrigerant passage is heated by a central processing unit mounted to the plate tube, boils, and becomes a gas-phase refrigerant, the first header tank is filled with the gas-phase refrigerant, and the gas-phase refrigerant flows from the upper side to the lower side in the tubes. The gas-phase refrigerant is cooled by cooling air in the tubes, is condensed, and flows to the second header tank under its own weight. The refrigerant circulates in the order of the first refrigerant passage, the first header tank, the tubes, the second header tank, and the first refrigerant passage.

In boiling coolers, when a refrigerant liquid on the inner surface of a boiling part (especially the inner surface of a location in which a heating element is installed) dries, the cooling performance of the heating element rapidly decreases because vaporization cooling cannot be performed. Therefore, it is important to reduce or prevent drying of the inner surface of the boiling part.

In Japanese Patent Laid-Open No. 8-204075, upward movement of the refrigerant gas to the condensing part and downward movement of a condensed refrigerant liquid to the evaporation part are carried out in the same path (an upper end opening of the evaporation part), and thus when the amount of vaporized refrigerant increases, the downward movement of the refrigerant liquid is inhibited by the rising refrigerant gas such that the dry cooling performance of the evaporation part tends to decrease.

On the other hand, in Japanese Patent Laid-Open No. 2005-101190, a movement path of a refrigerant gas and a movement path of a refrigerant liquid are different, and thus the phenomenon in which movement of the refrigerant liquid is inhibited by the refrigerant gas hardly occurs. However, especially when an external fluid is at a low temperature, a refrigerant pressure in a condensing part decreases, and the amount of vaporized refrigerant with respect to the amount of heat input tends to increase. Also in Japanese Patent Laid-Open No. 2005-101190, when the amount of heat input from a heating element increases and the external fluid is at a low temperature at which the amount of vaporized refrigerant tends to increase, the inner surface of a boiling part dries due to the insufficient amount of refrigerant liquid that is condensed and returned compared to the amount of vaporized refrigerant, and the cooling performance rapidly decreases.

### SUMMARY OF THE INVENTION

In response to the aforementioned problems, and one aspect of the present invention is directed to provide a boiling cooler capable of reducing or preventing a rapid decrease in cooling performance due to an increase in the amount of heat input even when an external fluid is at a low temperature.

A boiling cooler according to the aspect of the present invention includes a boiling part being operable to boil a refrigerant by heat exchange with a heating element, and a condensing part being operable to condense a refrigerant gas by heat exchange with an external fluid. The boiling part includes an accommodation space to accommodate the refrigerant, a refrigerant gas outlet connected to the accommodation space, a refrigerant liquid inlet connected to the accommodation space, a first wall to which the heating element is mounted, a second wall facing the first wall via the accommodation space and adjacent to an external passage, and a heat conductive portion to connect the first wall to the second wall through the accommodation space. The condensing part includes a refrigerant passage communicating with the refrigerant gas outlet and the refrigerant liquid inlet, and the external passage provided between the refrigerant passage and the boiling part to allow the external fluid to flow therethrough, and the condensing part is configured to receive the refrigerant gas through the refrigerant gas outlet, and send a condensed refrigerant liquid to the refrigerant liquid inlet.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a perspective view schematically showing the overall configuration of a cooler according to a first embodiment.

FIG. 2 is a schematic exploded perspective view of the cooler according to the first embodiment.

FIG. 3 is a schematic longitudinal sectional view of the cooler according to the first embodiment, taken along a YZ direction.

FIG. 4 is a schematic horizontal sectional view of the cooler according to the first embodiment, taken along an XY direction.

FIG. 5 is a partial enlarged view of FIG. 4.

FIG. 6 is a plan view of the inside of a boiling part as viewed in a Y direction.

FIG. 7 is a schematic enlarged sectional view of a condensing part, taken along the YZ direction.

FIG. 8 is a schematic perspective view showing the overall configuration of a cooler according to a second embodiment.

FIG. 9 is a schematic exploded perspective view of a boiling part according to the second embodiment.

FIG. 10 is a schematic horizontal sectional view of the cooler according to the second embodiment, taken along an XY direction.

FIG. 11 is a partial enlarged view of FIG. 10.

FIG. 12 is a schematic perspective view showing the overall configuration of a cooler according to a third embodiment.

FIG. 13 is a schematic longitudinal sectional view of the cooler according to the third embodiment, taken along a YZ direction.

FIG. 14 is a graph showing cooling performance measurement results of the cooler according to the first embodiment.

FIG. 15 is a graph showing cooling performance measurement results of the cooler according to the second embodiment.

FIG. 16 is a graph showing cooling performance measurement results of the cooler according to the third embodiment.

FIG. 17 is a schematic perspective view showing the overall configuration of a cooler according to a fourth embodiment.

FIG. 18 is a schematic exploded perspective view of the cooler according to the fourth embodiment.

FIG. 19 is a schematic sectional view of the inside of a boiling part according to the fourth embodiment, as viewed in a Y direction.

FIG. 20 is a schematic plan view of the boiling part according to the fourth embodiment, as viewed from the outside in the Y direction.

FIG. 21 is a schematic perspective view showing the overall configuration of a cooler according to a fifth embodiment.

FIG. 22 is a schematic exploded perspective view of the cooler according to the fifth embodiment.

FIG. 23 is a schematic longitudinal sectional view of the cooler according to the fifth embodiment, taken along a YZ direction.

FIG. 24 is a schematic sectional view of the inside of a boiling part according to the fifth embodiment, as viewed in a Y direction.

FIG. 25 is a schematic plan view of the boiling part according to the fifth embodiment, as viewed from the outside in the Y direction.

FIG. 26 is a schematic perspective view showing the overall configuration of a cooler according to a sixth embodiment.

FIG. 27 is a schematic exploded perspective view of the cooler according to the sixth embodiment.

FIG. 28 is a schematic sectional view of the inside of a boiling part according to the sixth embodiment, as viewed in a Y direction.

FIG. 29 is a schematic plan view of the boiling part according to the sixth embodiment, as viewed from the outside in the Y direction.

FIG. 30 is a schematic perspective view showing the overall configuration of a cooler according to a seventh embodiment.

FIG. 31 is a schematic exploded perspective view of the cooler according to the seventh embodiment.

FIG. 32 is a schematic sectional view of the inside of a boiling part according to the seventh embodiment, as viewed in a Y direction.

### DESCRIPTION OF THE PREFERRED EMBODIMENTS

Embodiments of the present invention are hereinafter described with reference to the drawings. The same reference numerals are used for the same or similar configurations.

### First Embodiment

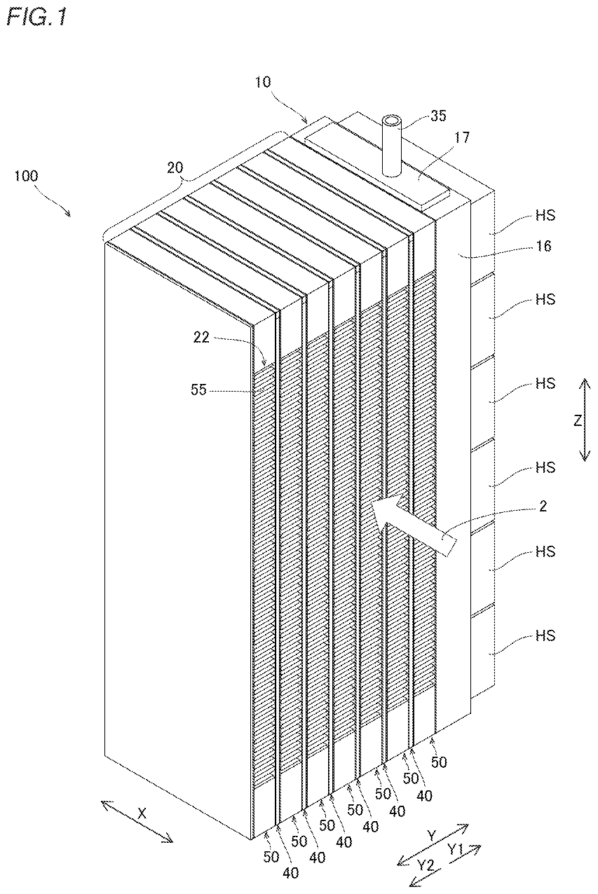

Referring to FIGS. 1 to 6, the configuration of a boiling cooler 100 (hereinafter referred to as a cooler 100) according to a first embodiment is now described. The cooler 100 is a boiling cooling type cooler that absorbs heat from heating elements HS and releases the heat to the outside, using a phase change which is vaporization or condensation of a refrigerant. The cooler 100 cools the heating elements HS by heat absorption of the refrigerant. A refrigerant gas vaporized due to the heat absorption is condensed and returned to a liquid phase by being cooled by an external fluid. The cooler 100 according to this embodiment further has a function of radiating heat from the heating elements HS to the outside by heat exchange with an external fluid 2 flowing through external passages 22 described below by transferring the heat from the heating elements HS to the external passages 22 by heat conduction.

The heating elements HS are not particularly limited. Each of the heating elements HS is a device including an electronic circuit, for example. Specifically, the heating element HS is a power module that constitutes a power conversion circuit such as an inverter device. A power module is a circuit component that includes one or more power conversion switching elements. The power conversion switching elements are IGBT (insulated gate bipolar transistor) elements, for example.

### Overall Configuration of Cooler

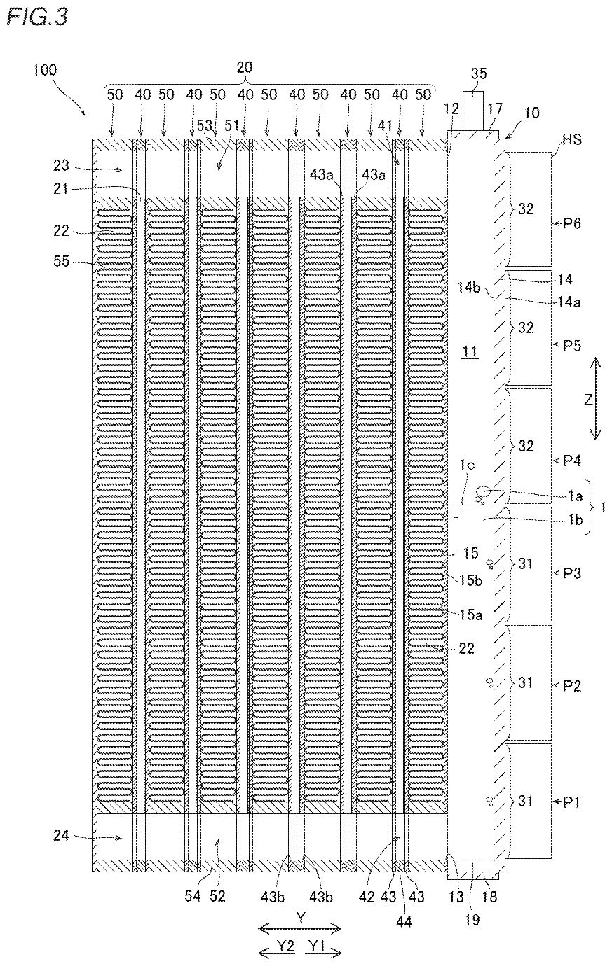

As shown in FIG. 1, the cooler 100 includes a boiling part 10 and a condensing part 20. A space (see FIG. 3) for accommodating a refrigerant 1 (see FIG. 3) is formed inside each of the boiling part 10 and the condensing part 20. The cooler 100 has an internal space sealed by the boiling part 10 and the condensing part 20. The refrigerant 1 is accommodated in this sealed space. The boiling part 10 and the condensing part 20 are made of metal materials with high thermal conductivity, such as aluminum (including aluminum alloys) or copper (including copper alloys).

The refrigerant 1 is not particularly limited as long as it changes its phase between a gas phase and a liquid phase. As the refrigerant 1, fluorocarbon, hydrocarbon, or water is used, for example. The internal space of the cooler 100 is filled with a single refrigerant 1, and is in a saturated vapor state due to the gas-phase refrigerant 1. When the states of the refrigerant 1 are distinguished, the gas-phase refrigerant 1 is referred to as a refrigerant gas 1a (see FIG. 3), and the liquid-phase refrigerant 1 is referred to as a refrigerant liquid 1b (see FIG. 3) for convenience. The external fluid 2 is air.

In the following, two directions perpendicular to each other in a horizontal plane are defined as an X direction and a Y direction. An upward-downward direction perpendicular to the horizontal plane (X-Y plane) is defined as a Z direction. The Z direction is parallel to the direction of gravity, and gravity acts in a downward direction.

The boiling part 10 and the condensing part 20 extend along the upward-downward direction (Z direction). A first side (Y1 direction side) of the boiling part 10 in the thickness direction (Y direction) is a mounting surface for the heating elements HS, and the condensing part 20 is provided on a second side (Y2 direction side) of the boiling part 10 in the thickness direction.

### Boiling Part

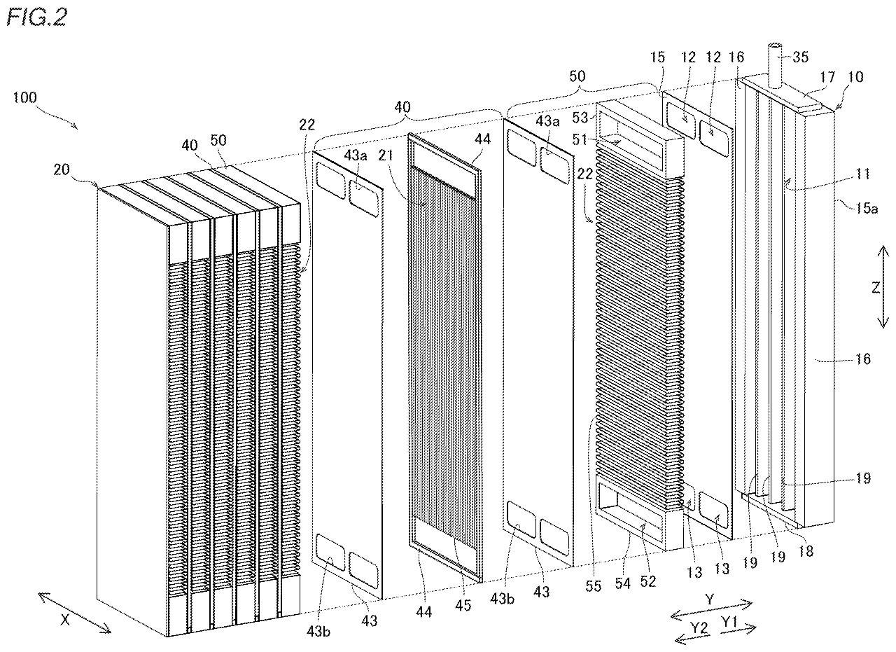

As shown in FIGS. 2 and 3, the boiling part 10 includes an accommodation space 11 for accommodating the refrigerant 1 (see FIG. 3), refrigerant gas outlets 12 connected to the accommodation space 11, and refrigerant liquid inlets 13 connected to the accommodation space 11. The refrigerant gas outlets 12 are arranged at an upper portion of the accommodation space 11, and the refrigerant liquid inlets 13 are arranged at a lower portion of the accommodation space 11. The boiling part 10 boils the refrigerant 1 by heat exchange with the heating elements HS.

As shown in FIG. 2, the boiling part 10 has a rectangular flat structure extending in the Z direction. The boiling part 10 is a plate-shaped hollow structure including a first wall 14 (see FIG. 3) on the first side (Y1 direction side) in the Y direction, a second wall 15 on the second side (Y2 direction side) in the Y direction, a pair of side walls 16 at both ends in the X direction, an upper wall 17 at the upper end in the Z direction, and a lower wall 18 at the lower end in the Z direction. The accommodation space 11 is a space surrounded by the first wall 14, the second wall 15, the pair of side walls 16, the upper wall 17, and the lower wall 18.

As shown in FIG. 3, the first wall 14 has a flat plate shape extending in the Z direction. The first wall 14 has an outer surface 14a that is a surface on the Y1 direction side, and an inner surface 14b that is a surface on the Y2 direction side.

The second wall 15 faces the first wall 14 in the Y direction through the accommodation space 11. The second wall 15 has an outer surface 15a that is a surface on the Y2 direction side, and an inner surface 15b that is a surface on the Y1 direction side. The condensing part 20 is provided on the outer surface 15a of the second wall 15. The second wall 15 is adjacent to the external passage 22 of the condensing part 20. In an example of FIG. 3, the outer surface 15a of the second wall 15 is exposed in the external passage 22 (defines the external passage 22). Moreover, the inner surface 15b of the second wall 15 is exposed in the accommodation space 11 (defines the accommodation space 11).

The refrigerant gas outlets 12 are provided in the vicinity of the upper end of the second wall 15. The refrigerant gas outlets 12 are through-holes (see FIG. 2) that pass through the second wall 15. The refrigerant gas outlets 12 communicate with the upper ends of refrigerant passages 21 of the condensing part 20.

The refrigerant liquid inlets 13 are provided in the vicinity of the lower end of the second wall 15. The refrigerant liquid inlets 13 are through-holes (see FIG. 2) that pass through the second wall 15. The refrigerant liquid inlets 13 communicate with the lower ends of the refrigerant passages 21 of the condensing part 20.

Due to the action of gravity, the liquid-phase refrigerant liquid 1b is stored in the lower portion of the accommodation space 11, and the gas-phase refrigerant gas 1a is accommodated in the upper portion of the accommodation space 11. The refrigerant 1 is introduced into the accommodation space 11 through a tube 35 provided on the upper wall 17, and the tube 35 is sealed after the refrigerant 1 is injected into the accommodation space 11. In the accommodation space 11, the refrigerant 1 is accommodated such that the liquid level 1c of the refrigerant liquid 1b is located at a height between the refrigerant gas outlets 12 and the refrigerant liquid inlets 13 in a non-operating state at room temperature with no heat input from the heating elements HS. In the example of FIG. 3, the liquid level 1c is set at a substantially intermediate position between the refrigerant gas outlets 12 and the refrigerant liquid inlets 13.

The outer surface 14a of the first wall 14 is a mounting surface for the heating elements HS, and six mounts are provided along the Z direction. Specifically, on the outer surface (outer surface 14a) of the first wall 14, first mounts 31 located below the liquid level 1c in the non-operating state and to which the heating elements HS are mounted, and second mounts 32 located above the liquid level 1c in the non-operating state and to which the heating elements HS are mounted are provided. In the first embodiment, three first mounts 31 and three second mounts 32 are provided on the first wall 14.

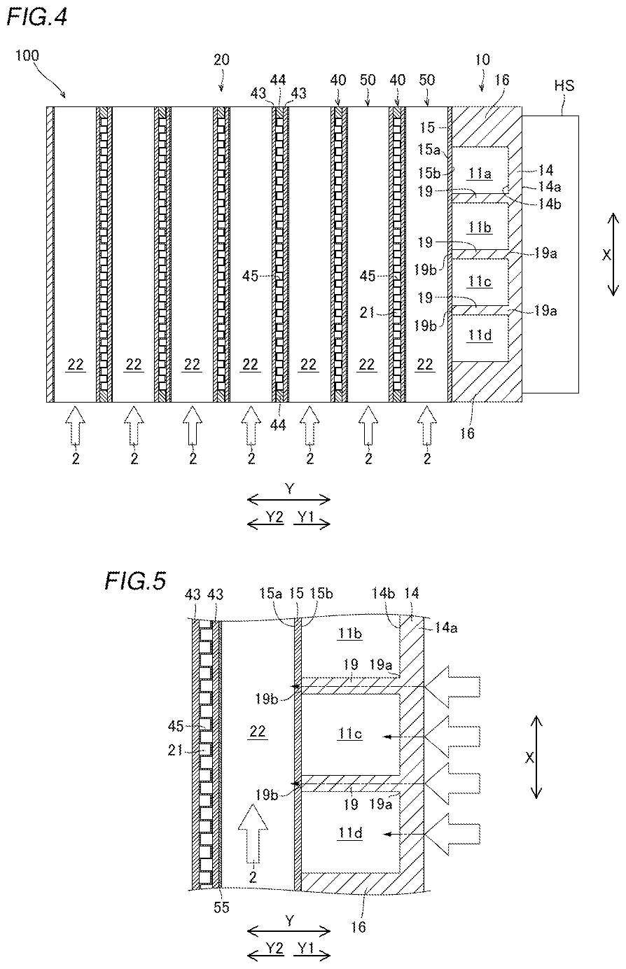

As shown in FIGS. 2 and 4, the boiling part 10 includes heat conductive portions 19 that connect the first wall 14 to the second wall 15 through the accommodation space 11. As shown in FIG. 5, first ends 19a of the heat conductive portions 19 in a Y1 direction contact the inner surface 14b of the first wall 14, and second ends 19b of the heat conductive portions 19 in a Y2 direction contact the inner surface 15b of the second wall 15. The heat conductive portions 19 are made of a metal material with high thermal conductivity such as aluminum (including aluminum alloys) or copper (including copper alloys). In this embodiment, the heat conductive portions 19 is made of the same material as the first wall 14 that constitutes the boiling part 10 as a portion of the boiling part 10. Therefore, the heat conductive portion 19 transfers heat applied to the first wall 14 from the heating elements HS to the second wall 15 by heat conduction.

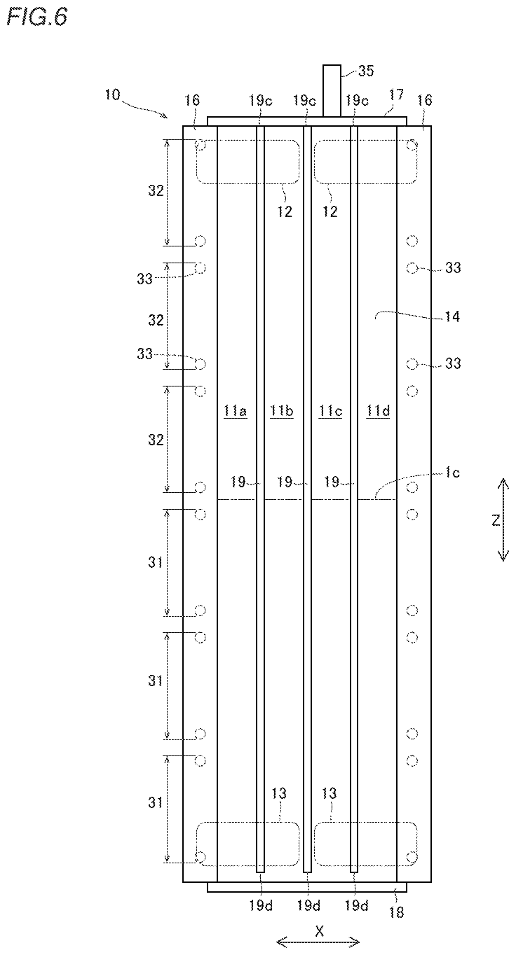

As shown in FIG. 6, the heat conductive portions 19 extend in a direction (Z direction) from the refrigerant liquid inlets 13 toward the refrigerant gas outlets 12 in the accommodation space 11, and a plurality of heat conductive portions 19 are provided in the accommodation space 11. In the first embodiment, the heat conductive portions 19 include partition walls in the accommodation space 11. Specifically, in the accommodation space 11, three heat conductive portions 19 are arranged at intervals in the X direction, and the accommodation space 11 is partitioned into four regions 11a to 11d. The three heat conductive portions 19 are arranged at equal intervals in the X direction, and the four regions 11a to 11d are spaces having substantially the same shape.

The heat conductive portions 19 are provided from the refrigerant gas outlets 12 to the refrigerant liquid inlets 13 in the accommodation space 11. Specifically, in the Z direction, the upper ends 19c of the heat conductive portions 19 extend to positions at which the refrigerant gas outlets 12 are provided, and the lower ends 19d of the heat conductive portions 19 extend to positions at which the refrigerant liquid inlets 13 are provided. In an example of FIG. 6, the upper ends 19c of the heat conductive portions 19 contact the upper wall 17 above the positions at which the refrigerant gas outlets 12 are provided, and the lower ends 19d of the heat conductive portions 19 extend to the vicinity of the lower wall 18 below the positions at which the refrigerant liquid inlets 13 are provided. That is, the heat conductive portions 19 are provided over substantially the entire length of the accommodation space 11 in the Z direction.

Therefore, the heat conductive portions 19 are provided across both a region below the liquid level 1c of the refrigerant 1 and a region above the liquid level 1c. The heat conductive portions 19 are provided across positions at which the six mounts (the three first mounts 31 and the three second mounts 32) are provided in the Z direction. The heat conductive portions 19 can cool the refrigerant liquid 1b in a portion below the liquid level 1c by heat exchange with the external fluid 2 via the second wall 15, and cool the refrigerant gas 1a in a portion above the liquid level 1c by heat exchange with the external fluid 2 via the second wall 15.

Mounting holes 33 are provided in the pair of side walls 16 of the boiling part 10 to mount the heating elements HS. The mounting holes 33 are provided at positions corresponding to the four corners of one heating element HS. The mounting holes 33 are screw holes, for example, and fastening members such as bolts are mounted thereto.

In the first embodiment, the first wall 14, the pair of side walls 16, and the three partition walls (heat conductive portions 19) of the boiling part 10 are integrally provided as a single member by extrusion molding or cutting. As shown in FIG. 2, the second wall 15, the upper wall 17, and the lower wall 18 are each joined to this single member.

### Condensing Part

As shown in FIG. 3, the condensing part 20 includes the refrigerant passages 21 through which the refrigerant 1 flows, and the external passages 22 through which the external fluid 2 flows. The refrigerant passages 21 communicate with the refrigerant gas outlets 12 and the refrigerant liquid inlets 13 of the boiling part 10. The condensing part 20 condenses the refrigerant gas 1a received through the refrigerant gas outlets 12 by heat exchange with the external fluid 2. In the refrigerant passages 21, the condensed refrigerant liquid 1b is sent to the refrigerant liquid inlets 13.

The condensing part 20 includes a plurality of refrigerant passages 21. The condensing part 20 further includes a refrigerant gas distribution passage 23 that connects the refrigerant gas outlets 12 of the boiling part 10 to the refrigerant passages 21, and a refrigerant liquid collection passage 24 that connects each refrigerant passage 21 to the refrigerant liquid inlets 13 of the boiling part 10.

The condensing part 20 has a structure in which flat plate-shaped first layers 40 that include the refrigerant passages 21 and flat plate-shaped second layers 50 that include connection passages 51 allowing the refrigerant passages 21 to communicate with the boiling part 10 and the external passages 22 are stacked.

In the example of FIG. 3, the condensing part 20 includes six first layers 40 and seven second layers 50. The first layers 40 and the second layers 50 are alternately stacked in the order of the second layer 50, the first layer 40, the second layer 50, the first layer 40, . . . , the first layer 40, and the second layer 50 from the boiling part 10 side (Y1 direction side).

### First Layer

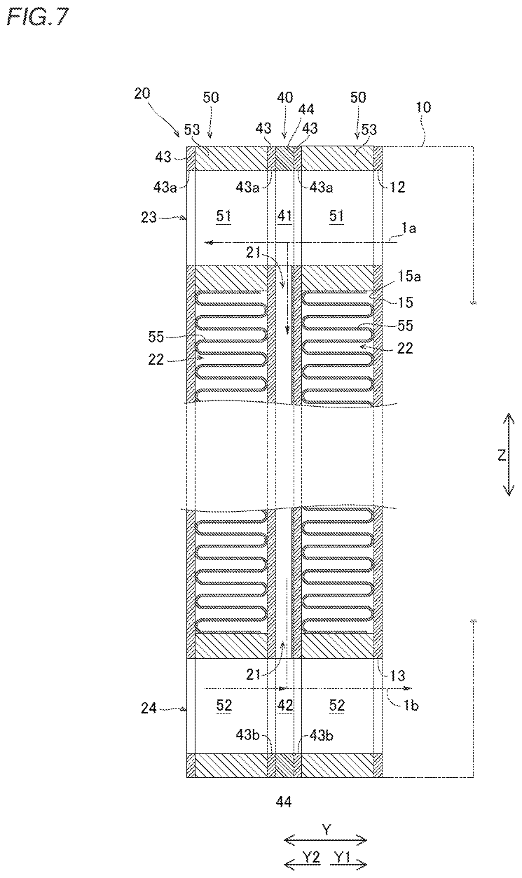

As shown in FIG. 7, each of the first layers 40 includes the refrigerant passage 21, the refrigerant gas inlet portion 41 communicating with the refrigerant passage 21, and a refrigerant liquid outlet portion 42 communicating with the refrigerant passage 21. The first layer 40 (refrigerant passage 21) is defined by partition plates 43 that partition the refrigerant passage 21 from the external passages 22, and a peripheral wall 44 (see FIG. 2) that defines the outer periphery of the refrigerant passage 21. As shown in FIG. 2, through-holes 43a are provided in the vicinity of the upper ends of the partition plates 43 to allow the refrigerant gas inlet portion 41 to communicate with the connection passages 51. Through-holes 43b are provided in the vicinity of the lower ends of the partition plates 43 to allow the refrigerant liquid outlet portion 42 to communicate with connection passages 52.

The partition plates 43 are rectangular flat plates extending in the Z direction, and partition the first layer 40 from the second layers 50 adjacent to the first layer 40. A pair of partition plates 43 are provided on the Y1 direction side and the Y2 direction side with respect to the refrigerant passage 21. The peripheral wall 44 is provided in an annular shape along the peripheral edges of the partition plates 43 between the pair of partition plates 43. The peripheral wall 44 is formed into a rectangular ring shape along the peripheral edges of the partition plates 43 by combining two L-shaped members corresponding to the two sides of each partition plate 43. Thus, the first layer 40 has a flat plate-shaped internal space defined by the pair of partition plates 43 and the annular peripheral wall 44.

The refrigerant passage 21 is a flat plate-shaped passage defined by the pair of partition plates 43 and the annular peripheral wall 44 and extending along the Z direction. The refrigerant passage 21 is adjacent to the external passages 22 of the second layers 50 via the partition plates 43, and heat exchange between the refrigerant gas 1a inside the refrigerant passage 21 and the external fluid 2 in the external passages 22 is performed via the partition plates 43. The refrigerant passage 21 has an upper end in the Z direction that is open to the refrigerant gas inlet portion 41 (see FIG. 7), and a lower end in the Z direction that is open to the refrigerant liquid outlet portion 42 (see FIG. 7).

The refrigerant passage 21 includes a corrugated fin 45 (see FIG. 2) that is integrated with the partition plates 43 and the peripheral wall 44 inside the refrigerant passage 21. The corrugated fin 45 is a plate member formed into a wave shape. As shown in FIG. 4, the corrugated fin 45 has both ends in the X direction that contact the peripheral wall 44, and both ends in the Y direction that contact the pair of partition plates 43. The corrugated fin 45, the peripheral wall 44, and the pair of partition plates 43 are joined to each other at contact points and integrated.

As shown in FIG. 7, the refrigerant gas inlet portion 41 is arranged at the upper end of the refrigerant passage 21. The refrigerant gas inlet portion 41 is connected to the connection passages 51 of the adjacent second layers 50 via the through-holes 43a of the partition plates 43. The refrigerant gas inlet portion 41 forms a portion of the refrigerant gas distribution passage 23.

The refrigerant liquid outlet portion 42 is arranged at the lower end of the refrigerant passage 21. The refrigerant liquid outlet portion 42 is connected to the connection passages 52 of the adjacent second layers 50 via the through-holes 43b of the partition plates 43. The refrigerant liquid outlet portion 42 forms a portion of the refrigerant liquid collection passage 24.

### Second Layer

As shown in FIG. 7, each of the second layers 50 includes the external passage 22, the upper connection passage 51 that constitutes the refrigerant gas distribution passage 23, and the lower connection passage 52 that constitutes the refrigerant liquid collection passage 24.

The external passage 22 is a passage that is open to the outside of the condensing part 20. Both sides of the external passage 22 in the Y direction are defined by the partition plates 43 that partition the first layer 40 from the second layers 50. The external passage 22 has an upper surface in the Z direction defined by an annular wall 53 (see FIG. 2) that defines the connection passage 51, and a lower surface in the Z direction defined by an annular wall 54 (see FIG. 2) that defines the connection passage 52. Both ends of the external passage 22 in the X direction are open to the outside of the condensing part 20 (see FIG. 1), and the external passage 22 passes through the condensing part 20 in the X direction.

A corrugated fin 55 is provided inside the external passage 22. The corrugated fin 55 is formed into a wave shape along the Z direction and extends along the X direction. Both ends of the corrugated fin 55 in the Y direction contact the pair of partition plates 43, respectively, the upper end of the corrugated fin 55 in the Z direction contacts the outer peripheral surface of the annular wall 53, and the lower end of the corrugated fin 55 in the Z direction contacts the outer peripheral surface of the annular wall 54. The corrugated fin 55, the pair of partition plates 43, and the annular walls 53 and 54 are joined to each other at contact points and integrated.

The connection passage 51 is an internal space of the upper annular wall 53. The annular wall 53 is provided so as to surround the through-holes 43a (refrigerant gas inlet portion 41) formed in the partition plates 43. Both ends of the annular wall 53 in the Y direction are joined to surfaces of the partition plates 43, respectively, such that the connection passage 51, which is the internal space of the annular wall 53, and the refrigerant gas inlet portion 41 of the refrigerant passage 21 communicate with each other. Similarly, the connection passage 52 is an internal space of the lower annular wall 54. The annular wall 54 is provided so as to surround the through-holes 43b (refrigerant liquid outlet portion 42) formed in the partition plates 43. Both ends of the annular wall 54 in the Y direction are joined to surfaces of the partition plates 43, respectively, such that the connection passage 52, which is the internal space of the annular wall 54, and the refrigerant liquid outlet portion 42 of the refrigerant passage 21 communicate with each other.

With this configuration, as shown in FIG. 3, seven (seven-layer) connection passages 51 and six (six-layer) refrigerant gas outlets 12 are alternately connected to the refrigerant gas outlets 12 of the boiling part 10 to configure one refrigerant gas distribution passage 23 extending in the Y direction. The refrigerant gas 1a flowing out from the refrigerant gas outlets 12 of the boiling part 10 flows into the refrigerant passage 21 of each of the six first layers 40 through the refrigerant gas distribution passage 23.

Furthermore, seven (seven-layer) connection passages 52 and six (six-layer) refrigerant liquid outlet portions 42 are alternately connected to the refrigerant liquid inlets 13 of the boiling part 10 to configure one refrigerant liquid collection passage 24 extending in the Y direction. The refrigerant liquid 1b condensed in the refrigerant passage 21 of each of the six first layers 40 moves downward to the corresponding refrigerant liquid outlet portion 42 due to the action of gravity, and flows into the refrigerant liquid inlets 13 of the boiling part 10 through the refrigerant liquid collection passage 24.

As shown in FIG. 7, the second layer 50 is arranged at an end of the condensing part 20 on the boiling part 10 side (Y1 direction side). The second layer 50 closest to the Y1 direction side contacts the second wall 15. The external passage 22 of the second layer 50 closest to the Y1 direction side is adjacent to the accommodation space 11 of the boiling part 10 via the second wall 15, the connection passage 51 is connected to the refrigerant gas outlets 12, and the connection passage 52 is connected to the refrigerant liquid inlets 13.

As described above, the cooler 100 according to this embodiment has a structure in which the flat plate-shaped boiling part 10, the flat plate-shaped first layers 40 of the condensing part 20, and the flat plate-shaped second layers 50 of the condensing part 20 are stacked in the Y direction. The cooler 100 is configured by integrating, by vacuum brazing, a stacked body in which the boiling part 10 and the condensing part 20 are stacked. Inside the first layer 40, the partition plates 43, the peripheral wall 44, and the corrugated fin 45 are integrated with each other by vacuum brazing. In the second layer 50, the annular wall 53, the annular wall 54, the corrugated fin 55, and the partition plates 43 (or the second wall 15) are integrated with each other.

### Operation of Cooler

The operation of the cooler 100 is now described. As the heating elements HS that are power modules operate, the heating elements HS generate heat. When the heating elements HS are cooled, air as the external fluid 2 is sent into the external passage 22 by a blower (not shown) installed outside the cooler 100.

In FIG. 3, the heat generated by the heating elements HS is transferred to the first wall 14 at the respective mounts. The heat transferred from the first mounts 31 below the liquid level 1c is absorbed by the refrigerant liquid 1b contacting the inner surface 14b of the first wall 14, and the refrigerant liquid 1b in the vicinity of the inner surface 14b boils and becomes a refrigerant gas 1a. The refrigerant gas 1a moves upward toward the refrigerant gas outlets 12. A portion of the refrigerant liquid 1b is lifted up by the refrigerant gas 1a as the refrigerant gas 1a moves upward such that in the region above the liquid level 1c, the refrigerant liquid 1b adheres to the inner surface 14b of the first wall 14, the surfaces of the heat conductive portions 19, and the inner surface 15b of the second wall 15.

Concurrently with heat absorption by the refrigerant 1, the heat transferred to the first wall 14 is transferred to the second wall 15 via the heat conductive portions 19 and is absorbed by the external fluid 2 flowing through the external passage 22 adjacent to the second wall 15, as shown in FIG. 5. A portion of the refrigerant gas 1a comes into contact with the heat conductive portions 19 and the second wall 15 while moving toward the refrigerant gas outlets 12, releases heat to the heat conductive portions 19 and the second wall 15, and is condensed. Consequently, even in the region above the liquid level 1c in the accommodation space 11, the condensed refrigerant liquid 1b adheres to the inner surface 14b of the first wall 14, the surfaces of the heat conductive portions 19, and the inner surface 15b of the second wall 15. In this manner, the refrigerant liquid 1b lifted by the refrigerant gas 1a and the refrigerant liquid 1b condensed by heat release to the external fluid 2 adhere to each surface in the region above the liquid level 1c in the accommodation space 11.

Returning to FIG. 3, the heat transferred from the second mounts 32 above the liquid level 1c is transferred to the second wall 15 via the first wall 14 and the heat conductive portions 19. In this process, the heat transferred from the second mounts 32 is absorbed by the refrigerant liquid 1badhering to each surface of the first wall 14, the heat conductive portions 19, and the second wall 15, and the external fluid 2 flowing through the external passage 22 adjacent to the second wall 15. The refrigerant liquid 1b that has absorbed the heat boils and becomes a refrigerant gas 1a.

The refrigerant gas 1a that has reached the refrigerant gas outlets 12 passes through the refrigerant gas outlets 12 and flows into the refrigerant gas distribution passage 23 of the condensing part 20. Then, the refrigerant gas 1a flows (is distributed) into the refrigerant passages 21 via the refrigerant gas inlet portions 41 of the first layers 40.

The refrigerant gas 1a that has flowed into each refrigerant passage 21 exchanges heat with the external fluid 2 flowing through the external passages 22 adjacent to the refrigerant passage 21 via the partition plates 43 and is cooled. Consequently, the refrigerant gas 1a in the refrigerant passage 21 is condensed into a refrigerant liquid 1b, and moves downward toward the refrigerant liquid outlet portion 42 due to the action of gravity.

The liquid level 1c of the refrigerant 1 is set in the vicinity of the intermediate position between the refrigerant gas outlets 12 and the refrigerant liquid inlets 13 of the boiling part 10, and thus also in the refrigerant passage 21, the liquid level 1c is located in the vicinity of an intermediate position between the refrigerant gas inlet portion 41 and the refrigerant liquid outlet portion 42. When the condensed refrigerant liquid 1b reaches the liquid level 1c in the refrigerant passage 21, it merges with the stored refrigerant liquid 1b. In a lower portion of the refrigerant passage 21 from the liquid level 1c to the refrigerant liquid outlet portion 42, the refrigerant liquid 1b is cooled by heat exchange with the external fluid 2 flowing through the external passage 22, and enters a subcooled state.

As the refrigerant liquid 1b vaporizes in the boiling part 10, the liquid level 1c of the refrigerant liquid 1b in the accommodation space 11 tends to lower, but in each refrigerant passage 21 in the condensing part 20, the condensed refrigerant liquid 1b is added and the liquid level 1c tends to rise. Thus, the refrigerant liquid 1b flows from the condensing part 20 into the refrigerant liquid inlets 13 of the boiling part 10 through the refrigerant liquid collection passage 24 so as to eliminate a water level difference between the liquid level 1c of the refrigerant liquid 1b in the accommodation space 11 and the liquid level 1c of the refrigerant liquid 1b in the refrigerant passage 21. Therefore, the refrigerant 1 circulates in the order of the boiling part 10 (accommodation space 11), the refrigerant gas distribution passage 23, each refrigerant passage 21, the refrigerant liquid collection passage 24, and the boiling part 10 (accommodation space 11) while undergoing a phase change.

As a result of the above operation, the heating elements HS are cooled by vaporization of the refrigerant liquid 1b in the accommodation space 11, and are also cooled by direct heat exchange with the external fluid 2 (not via the refrigerant 1) by heat conduction via the first wall 14, the heat conductive portions 19, and the second wall 15.

### Advantageous Effects of First Embodiment

According to the first embodiment, the following advantageous effects are achieved.

According to the first embodiment, as described above, the boiling part 10 includes the accommodation space 11 to accommodate the refrigerant 1, the refrigerant gas outlets 12 connected to the accommodation space 11, and the refrigerant liquid inlets 13 connected to the accommodation space 11, and thus a movement path of the refrigerant gas 1a going from the boiling part 10 to the condensing part 20 and a movement path of the refrigerant liquid 1b returning from the condensing part 20 to the boiling part 10 can be made different. Therefore, inhibition of movement of the refrigerant liquid 1b by the refrigerant gas 1a can be reduced or prevented. Furthermore, the boiling part 10 includes the first wall 14 to which the heating elements HS are mounted, the second wall 15 facing the first wall 14 via the accommodation space 11 and adjacent to the external passage 22, and the heat conductive portions 19 to connect the first wall 14 to the second wall 15 through the accommodation space 11, and thus the heat applied to the first wall 14 from the heating elements HS can be transferred to the second wall 15 by heat conduction through the heat conductive portions 19 to be directly released (not via the refrigerant 1) to the external fluid 2 flowing through the external passage 22 adjacent to the second wall 15. Therefore, even when the amount of heat input increases and the refrigerant 1 dries on the inner surface of the boiling part 10, the heat from the heating elements HS can be directly released to the external fluid 2 via the heat conductive portions 19, and thus a rapid decrease in cooling performance can be reduced or prevented. The amount of heat released directly to the external fluid 2 increases as the temperature of the external fluid 2 decreases, and thus it is particularly effective when the external fluid 2 is at a low temperature. Furthermore, the second wall 15, the heat conductive portions 19, and the first wall 14 are cooled by heat exchange with the external fluid 2, and thus a portion of the refrigerant gas 1a in the accommodation space 11 is condensed by contacting the second wall 15 and the heat conductive portions 19. Thus, the effect of reducing or preventing drying of the refrigerant 1 on the inner surface of the boiling part 10 can be obtained. Consequently, even when the external fluid 2 is at a low temperature, a rapid decrease in cooling performance due to an increase in the amount of heat input can be reduced or prevented.

According to the first embodiment, as described above, the heat conductive portions 19 extend in the direction from the refrigerant liquid inlets 13 toward the refrigerant gas outlets 12 in the accommodation space 11, and the plurality of heat conductive portions 19 are provided in the accommodation space 11. Accordingly, movement of the refrigerant gas 1a toward the refrigerant gas outlets 12 is not hindered by the heat conductive portions 19, and the amount of heat transferred by the heat conductive portions 19 can be effectively increased. Furthermore, the surface area of the heat conductive portions 19 in the accommodation space 11 can be increased, and thus the effect of condensing a portion of the refrigerant gas 1a due to contact between the heat conductive portions 19 and the refrigerant gas 1a can be improved.

According to the first embodiment, as described above, the heat conductive portions 19 include the partition walls in the accommodation space 11. Accordingly, the heat conductive portions 19 can be provided in the accommodation space 11 with a simple structure, and the heat conductive portions 19 can also function as reinforcing structures to ensure the mechanical strength of the boiling part 10.

According to the first embodiment, as described above, the heat conductive portions 19 are provided from the refrigerant gas outlets 12 to the refrigerant liquid inlets 13 in the accommodation space 11. Accordingly, the heat conductive portions 19 can be provided over a wide range in the accommodation space 11, and thus the amount of heat transferred by the heat conductive portions 19 can be effectively increased. Furthermore, portions of the heat conductive portions 19 that are immersed in the refrigerant liquid 1b can cool the refrigerant liquid 1b to a subcooled state, and thus the effect of reducing the amount of generated refrigerant gas 1a can be obtained. Portions of the heat conductive portions 19 that contact the refrigerant gas 1a have the effect of condensing a portion of the refrigerant gas 1a to reduce or prevent drying of the refrigerant 1, as described above.

According to the first embodiment, as described above, the first mounts 31 located below the liquid level 1c in the non-operating state and to which the heating elements HS are mounted, and the second mounts 32 located above the liquid level 1c in the non-operating state and to which the heating elements HS are mounted are provided on the outer surface of the first wall 14. Accordingly, the heating elements HS can be cooled not only on the first mounts 31 arranged on the outer surface at a position immersed in the refrigerant liquid 1b, but also on the second mounts 32 arranged on the outer surface at a position away from the refrigerant liquid 1b. Generally, at a position above the liquid level 1c, the inner surface 14b of the first wall 14 is in a dry state, and thus the cooling performance is decreased. However, in the first embodiment, the above-described effect of the heat conductive portions 19 can be obtained, and as the boiled refrigerant gas 1a rises, a portion of the refrigerant liquid 1b is lifted upward from the liquid level 1c, and thus the effect that the refrigerant liquid 1b adheres to the inner surface of the accommodation space 11 at the position above the liquid level 1c can be obtained. Consequently, sufficient cooling performance can be obtained even at the second mounts 32 located above the liquid level 1c.

According to the first embodiment, as described above, the refrigerant passage 21 includes the partition plates 43 to partition the refrigerant passage 21 from the external passages 22, the peripheral wall 44 to define the outer periphery of the refrigerant passage 21, and the corrugated fin 45 integrated with the partition plates 43 and the peripheral wall 44 inside the refrigerant passage 21. Accordingly, the heat exchange efficiency between the refrigerant gas 1a passing through the refrigerant passage 21 and the external fluid 2 passing through the external passage 22 can be improved.

According to the first embodiment, as described above, the condensing part 20 has a structure in which the flat plate-shaped first layer 40 including the refrigerant passage 21 and the flat plate-shaped second layer 50 including the connection passage 51 to allow the refrigerant passage 21 and the boiling part 10 to communicate with each other and the external passage 22 are stacked, and the condensing part 20 is stacked on the second wall 15 of the boiling part 10 and integrated with the boiling part 10. Accordingly, the second layer 50 and the first layer 40 are stacked in this order on the boiling part 10, and the stacked body is integrated by a joining method such as brazing such that the boiling cooler 100 can be configured. The boiling cooler 100 has a simple stacked structure, and thus the boiling cooler 100 can be easily obtained.

### Second Embodiment

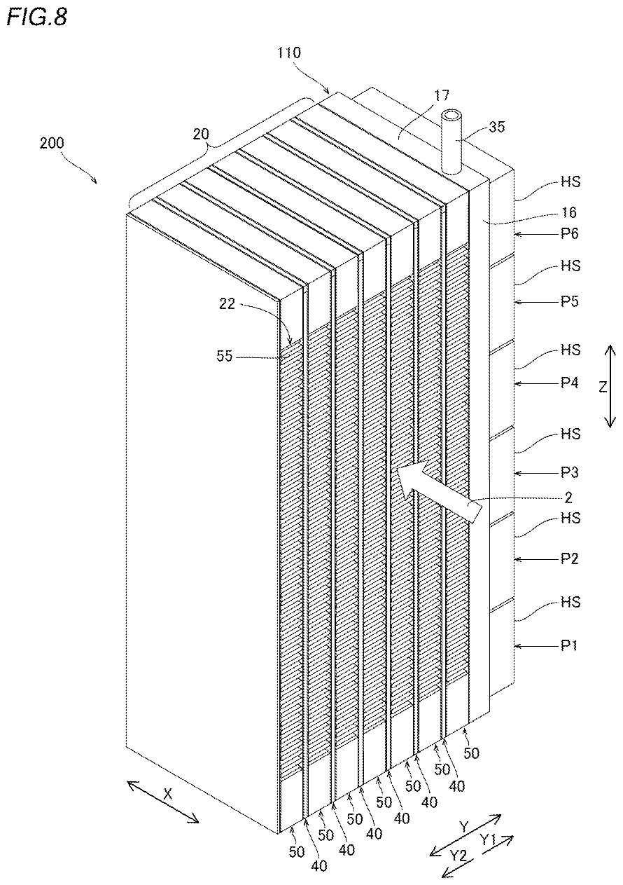

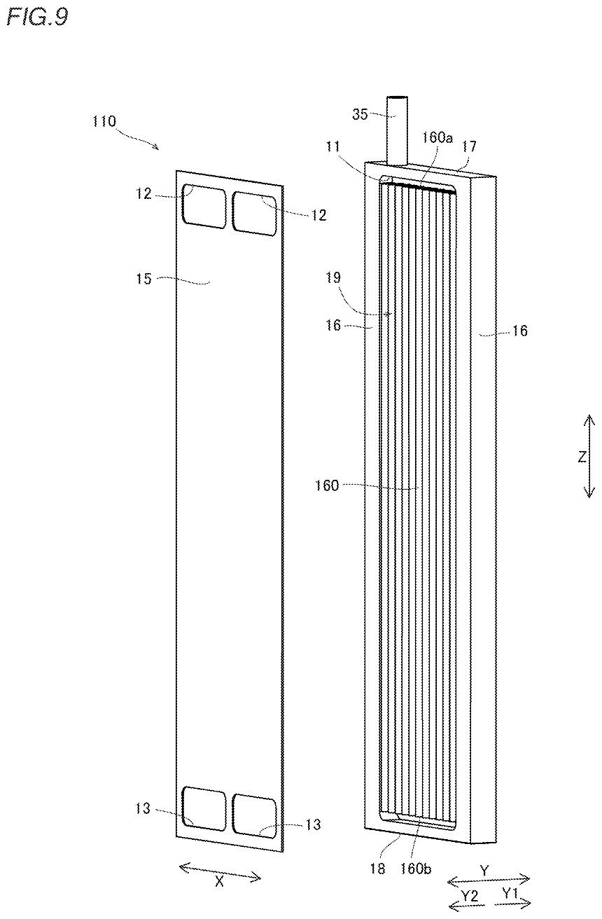

Referring to FIGS. 8 to 11, the configuration of a boiling cooler 200 (hereinafter referred to as a cooler 200) according to a second embodiment of the present invention is now described. In the second embodiment, a heat conductive portion 19 includes a corrugated fin 160 (see FIG. 9).

In the second embodiment, configurations other than a boiling part 110 are the same as those of the first embodiment. Only the configuration of the boiling part 110 of the second embodiment is described below.

As shown in FIG. 8, the cooler 200 according to the second embodiment includes the boiling part 110. As shown in FIG. 9, the heat conductive portion 19 of the boiling part 110 includes the corrugated fin 160 in an accommodation space 11.

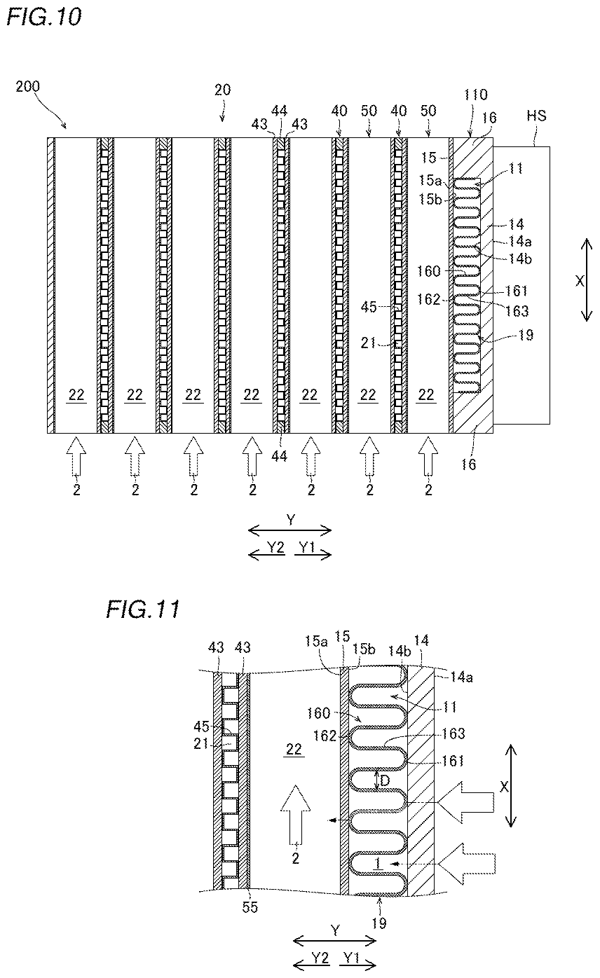

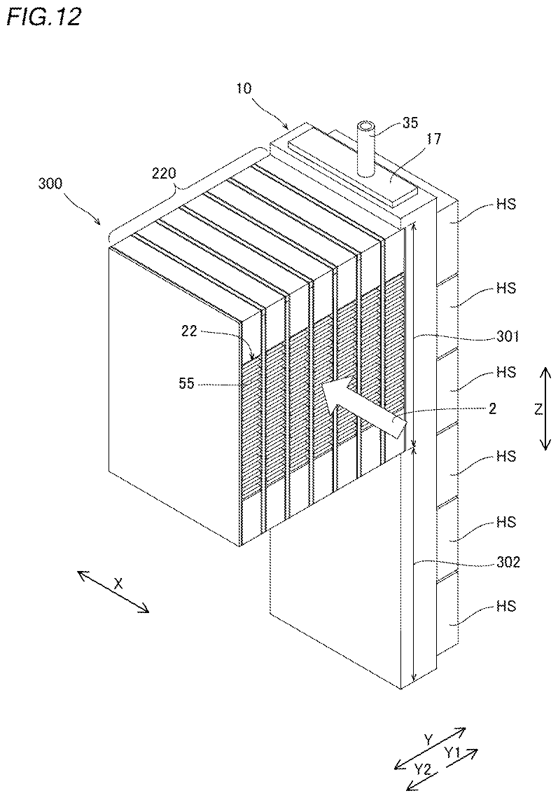

As shown in FIGS. 10 and 11, the corrugated fin 160 includes first portions 161 that contact a first wall 14, second portions 162 that contact a second wall 15, and third portions 163 that extend in a Y direction and connect the first portions 161 to the second portions 162. Each of the first portions 161 and the second portions 162 is a bent portion of the wavy corrugated fin 160, and is provided periodically at regular intervals in an X direction. The third portions 163 are flat plate-shaped portions that connect the bent portions to each other.

Thus, the heat conductive portion 19 including the corrugated fin 160 is connected to the inner surface of the first wall 14 at the first portions 161 and is connected to the inner surface of the second wall 15 at the second portions 162. As shown in FIG. 11, heat applied to the first wall 14 is transferred to the second wall 15 through the first portions 161, the third portions 163, and the second portions 162 by heat conduction. The corrugated fin 160 includes a plurality of (twenty-one in FIG. 10) third portions 163 at a predetermined interval D, and each third portion 163 serves as a heat conduction path between the first wall 14 and the second wall 15. Therefore, in the second embodiment, more heat conduction paths (third portions 163) are distributed and provided over the entire width of the accommodation space 11 in the X direction, as compared with the first embodiment in which three heat conductive portions 19 (partition walls) are provided.

The entire outer surface of the corrugated fin 160 excluding contact points with the first wall 14 and contact points with the second wall 15 becomes a heat transfer surface that exchanges heat with a refrigerant 1 in the accommodation space 11. Therefore, in the second embodiment, as compared with the first embodiment in which three heat conductive portions 19 (partition walls) are provided, the heat transfer area of the heat conductive portion 19 in the accommodation space 11 can be increased, and thus the effect of cooling a refrigerant liquid 1b and condensing a refrigerant gas 1a is improved.

As shown in FIG. 9, in the second embodiment, the heat conductive portion 19 (corrugated fin 160) is provided from refrigerant gas outlets 12 to refrigerant liquid inlets 13 in the accommodation space 11, similarly to the first embodiment. In a Z direction, the upper end 160a of the corrugated fin 160 is arranged at a position that overlaps with a range in which the refrigerant gas outlets 12 are provided, and the lower end 160b of the corrugated fin 160 is arranged at a position that overlaps with a range in which the refrigerant liquid inlets 13 are provided. The heat conductive portion 19 (corrugated fin 160) is provided continuously from the refrigerant gas outlets 12 to the refrigerant liquid inlets 13 without interruption.

The boiling part 110 according to the second embodiment is formed by cutting a flat plate member. That is, the accommodation space 11 is formed by a recess formed on the second wall 15 side of the flat plate member. Therefore, in the boiling part 110, an upper wall portion 17, a lower wall portion 18, a pair of side wall portions 16, and the first wall 14 are integrally formed. After the corrugated fin 160 is housed in the accommodation space 11 of the flat plate member, the accommodation space 11 is closed with the second wall 15, and the flat plate member, the corrugated fin 160, and the second wall 15 are integrated together with the condensing part 20 by vacuum brazing such that the boiling part 110 is configured.

The remaining configurations of the second embodiment are similar to those of the first embodiment.

### Advantageous Effects of Second Embodiment

According to the second embodiment, similarly to the first embodiment, the boiling part 10 includes the accommodation space 11 to accommodate the refrigerant 1, the refrigerant gas outlets 12 connected to the accommodation space 11, and the refrigerant liquid inlets 13 connected to the accommodation space 11, and thus inhibition of movement of the refrigerant liquid 1b by the refrigerant gas 1a can be reduced or prevented. Furthermore, the boiling part 10 includes the first wall 14 to which heating elements HS are mounted, the second wall 15 facing the first wall 14 via the accommodation space 11 and adjacent to an external passage 22, and the heat conductive portion 19 to connect the first wall 14 to the second wall 15 through the accommodation space 11, and thus the heat applied to the first wall 14 from the heating elements HS can be transferred to the second wall 15 by heat conduction through the heat conductive portion 19 to be directly released (not via the refrigerant 1) to an external fluid 2 flowing through the external passage 22 adjacent to the second wall 15. Moreover, a portion of the refrigerant gas 1a in the accommodation space 11 is condensed, and thus the effect of reducing or preventing drying of the refrigerant 1 on the inner surface of the boiling part 10 can be obtained. Consequently, even when the external fluid 2 is at a low temperature, a rapid decrease in cooling performance due to an increase in the amount of heat input can be reduced or prevented.

According to the second embodiment, as described above, the heat conductive portion 19 includes the corrugated fin 160 in the accommodation space 11. Accordingly, the amount of heat transferred by the heat conductive portion 19 can be further increased by the corrugated fin 160.

The remaining advantageous effects of the second embodiment are similar to those of the first embodiment.

### Third Embodiment

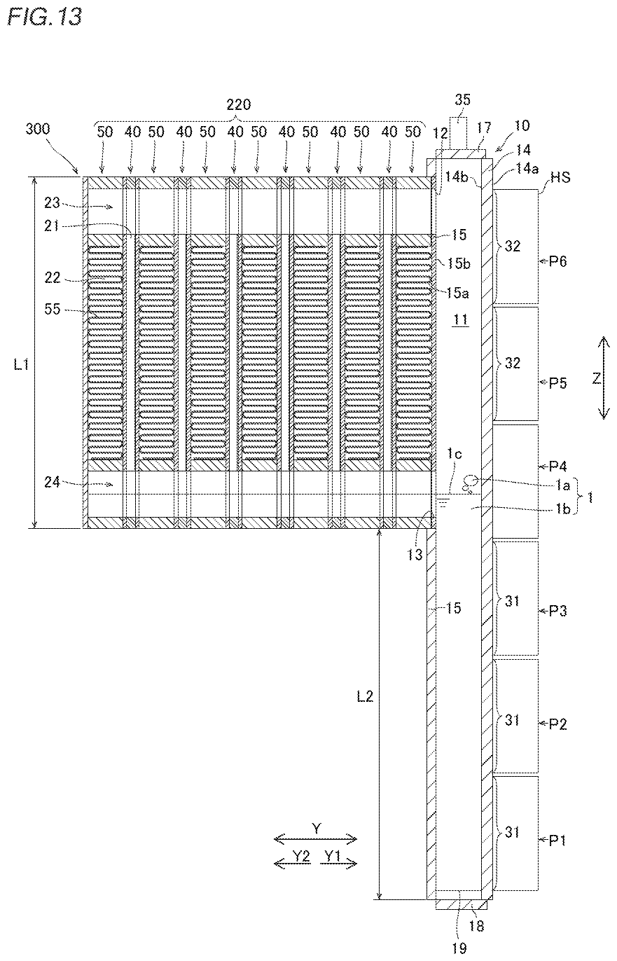

Referring to FIGS. 12 to 13, the configuration of a boiling cooler 300 (hereinafter referred to as a cooler 300) according to a third embodiment of the present invention is now described. In the third embodiment, a condensing part 220 is provided on a portion of a boiling part 10 on the upper side in a Z direction.

In the third embodiment, configurations other than a range in which the condensing part 220 is provided are the same as those of the first embodiment.

As shown in FIG. 12, in the cooler 300 according to the third embodiment, the condensing part 220 is provided on an upper first region 301 of the boiling part 10, and the condensing part 220 is not provided on a remaining (lower) second region 302 of the boiling part 10.

As shown in FIG. 13, the first region 301 (see FIG. 12) on which the condensing part 220 is provided is a region having a length L1 in the Z direction, and the length L1 is substantially half of the total length of the boiling part 10. Therefore, in the third embodiment, the condensing part 220 is provided in substantially the upper half of the boiling part 10. The second region 302 (see FIG. 12) is a region having a length L2 in the Z direction, and the length L2 is substantially half of the total length of the boiling part 10. The width dimension (X-direction dimension) of the condensing part 220 and the width dimension (X-direction dimension) of the boiling part 10 are substantially equal, and the condensing part 220 is provided over the entire width of the boiling part 10.

Refrigerant passages 21 of the condensing part 220 are provided above the liquid level 1c of a refrigerant liquid 1b in a non-operating state at room temperature with no heat input from heating elements HS. That is, the lower ends of the refrigerant passages 21 are located at a height equal to or higher than the liquid level 1c. In an example of FIG. 13, the liquid level 1c is set at an intermediate position of a refrigerant liquid collection passage 24 in the Z direction. In the third embodiment, the refrigerant liquid 1b does not remain in the refrigerant passages 21 of the condensing part 220, and thus the refrigerant liquid 1b passes through the refrigerant passages 21 without remaining in the refrigerant passages 21 and significantly inhibiting heat transfer in the refrigerant passages 21, and is stored in an accommodation space 11 of the boiling part 10.

The remaining configurations of the third embodiment are similar to those of the first embodiment.

### Advantageous Effects of Third Embodiment

According to the third embodiment, similarly to the first embodiment, the boiling part 10 includes the accommodation space 11 to accommodate a refrigerant 1, refrigerant gas outlets 12 connected to the accommodation space 11, and refrigerant liquid inlets 13 connected to the accommodation space 11, and thus inhibition of movement of the refrigerant liquid 1b by a refrigerant gas 1a can be reduced or prevented. Furthermore, the boiling part 10 includes a first wall 14 to which the heating elements HS are mounted, a second wall 15 facing the first wall 14 via the accommodation space 11 and adjacent to an external passage 22, and heat conductive portions 19 to connect the first wall 14 to the second wall 15 through the accommodation space 11, and thus heat applied to the first wall 14 from the heating elements HS can be transferred to the second wall 15 by heat conduction through the heat conductive portions 19 to be directly released (not via the refrigerant 1) to an external fluid 2 flowing through the external passage 22 adjacent to the second wall 15. Moreover, a portion of the refrigerant gas 1a in the accommodation space 11 is condensed, and thus the effect of reducing or preventing drying of the refrigerant 1 on the inner surface of the boiling part 10 can be obtained. Consequently, even when the external fluid 2 is at a low temperature, a rapid decrease in cooling performance due to an increase in the amount of heat input can be reduced or prevented.

The remaining advantageous effects of the third embodiment are similar to those of the first embodiment.

EXAMPLES

Experimental results for confirming the effects of the coolers according to the first to third embodiments are now described.

### Experiment Description

The cooling performance of each of the cooler 100 according to the first embodiment, the cooler 200 according to the second embodiment, and the cooler 300 according to the third embodiment was measured in a state in which heating elements HS for testing were mounted and heated. At that time, air was sent to the external passages 22 of the condensing part 20 at a predetermined amount. The surface temperature of the mounting surfaces (the outer surface 14a of the first wall 14) of the heating elements HS and the refrigerant temperature in the accommodation space 11 of the boiling part 10 were measured, and a temperature difference ΔT between the measured surface temperature and refrigerant temperature was obtained as an index of cooling performance. The measurement results show that as the temperature difference ΔT decreases, the cooling performance of the boiling part 10 increases.

The six mounts shown in each embodiment are distinguished as P1 to P6 (see FIGS. 3, 8, and 13) from the bottom to the top in the Z direction. P1 to P3 are the first mounts 31 below the liquid level 1c, and P4 to P6 are the second mounts 32 above the liquid level 1c (only in the third embodiment, the mount P4 is across the liquid level 1c).

Heating was performed under the following two types of conditions.

(Condition 1) Heating is performed by the six heating elements HS at the mounts P1 to P6.

(Condition 2) Heating is performed by only the three heating elements HS at the upper mounts P4 to P6, and not performed at the lower mounts P1 to P3.

Then, under the condition 1, the temperature difference ΔT at the top mount P6 farthest from the liquid level 1c of the refrigerant 1 and the highest value of the temperature differences ΔT at the lower three mounts P1 to P3 were acquired. Under the condition 2, the temperature difference ΔT at the top mount P6 farthest from the liquid level 1c of the refrigerant 1 was acquired. During temperature measurement, the amount of heat (heat generation density [W/cm2]) generated by each heating element HS was changed in a stepwise manner, and the temperature difference ΔT in each amount of heat generated was acquired.

### Experimental Results

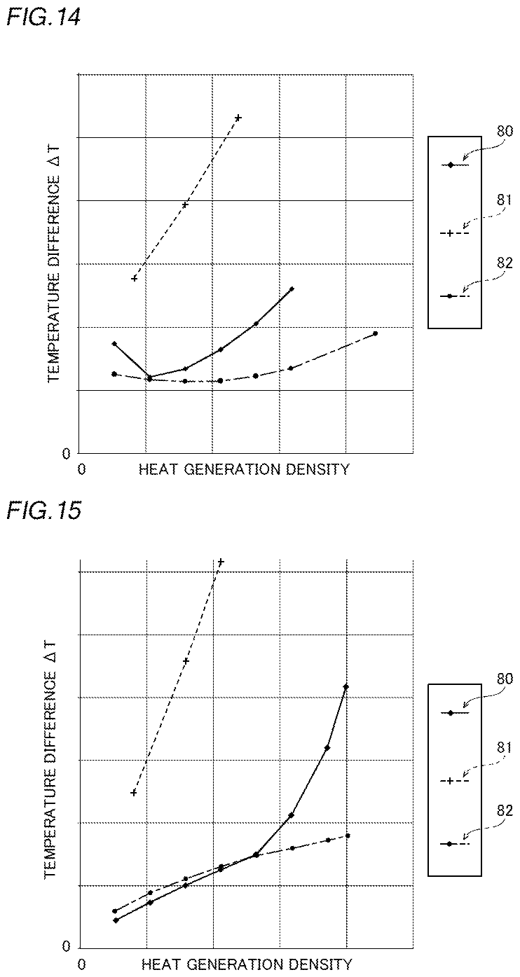

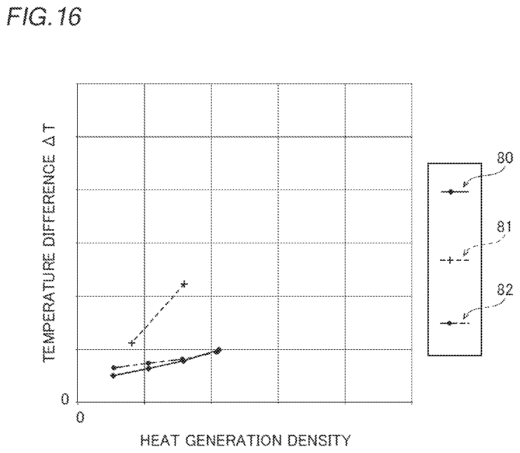

FIGS. 14 to 16 are graphs showing the measurement results of the cooling performance of the cooler 100 according to the first embodiment, the cooler 200 according to the second embodiment, and the cooler 300 according to the third embodiment, respectively.

The horizontal axis of each graph in FIGS. 14 to 16 indicates the heat generation density [W/cm2] of the heating element HS. The vertical axis of each graph indicates the temperature difference ΔT [K]. Each of the graphs in FIGS. 14 to 16 shows an approximate curve obtained from a plot of the temperature difference ΔT measured at each heat generation density. In each graph in FIGS. 14 to 16, a solid line legend 80 shows the measurement results at the mount P6 under the condition 1. In each graph in FIGS. 14 to 16, a broken line legend 81 shows the measurement results at the mount P6 under the condition 2. In each graph in FIGS. 14 to 16, a one-dot chain line legend 82 shows the measurement results of the highest value of the temperature differences ΔT at the mounts P1 to P3 under the condition 1. The measurement results (approximate curve) at the mount P6 under the condition 1 are shown by the solid line legend 80, the measurement results (approximation curve) at the mount P6 under the condition 2 are shown by the broken line legend 81, and the measurement results (approximate curve) of the highest value of the temperature differences ΔT at the mounts P1 to P3 under the condition 1 are shown by the one-dot chain line legend 82.

From the graphs in FIGS. 14 to 16, similar trends were confirmed for the coolers 100 to 300. Specifically, in a case of the “condition 2” in which heating was performed only by the three heating elements HS at the upper mounts P4 to P6 (second mounts 32), the temperature difference ΔT (broken line legend 81) at the mount P6 sharply increased even with a relatively low amount of heat generated. On the other hand, due to the effect of the heat conductive portion(s) 19, the temperature did not go out of control and remained at a certain high temperature. As compared with the measurement results under the condition 2, it has been confirmed that under the “condition 1” in which heating is performed by the six heating elements HS at the mounts P1 to P6, the temperature difference ΔT (solid line legend 80) at the same mount P6 is significantly lower.

Regarding two measurement results under the “condition 1”, it has been confirmed that a difference between the measurement result (solid line legend 80) at the mount P6 above the liquid level 1c and the measurement result (one-dot chain line legend 82) at the mount P1, P2, or P3 below the liquid level 1c is sufficiently small as compared with a difference between the measurement result (solid line legend 80) at the mount P6 above the liquid level 1c and the measurement result under the condition 2 shown by the broken line legend 81.

From these results, it has been confirmed that in the coolers 100 to 300 according to the first to third embodiments, the cooling performance close to that at the first mounts 31 can be obtained not only for the heating elements HS at the first mounts 31 but also for the heating elements HS mounted to the second mounts 32 above the liquid level 1c when the heating elements HS are mounted to both the first mounts 31 below the liquid level 1c of the refrigerant 1 and the second mounts 32 above the liquid level 1c, and cooled.

From this, in the coolers 100 to 300 according to the first to third embodiments, heat is input to the first mounts 31 below the liquid level 1c, in a situation (condition 1) in which a sufficient amount of vaporization is ensured, a portion of the refrigerant gas 1a rising from the liquid level 1c comes into contact with the second wall 15 and the heat conductive portion(s) 19, which are cooled by heat exchange with the external fluid 2, and is condensed to adhere to the inner surface of the accommodation space 11 at the position above the liquid level 1c, and as the boiled refrigerant gas 1a rises, a portion of the refrigerant liquid 1b is lifted upward from the liquid level 1c to adhere to the inner surface of the accommodation space 11 at the position above the liquid level 1c. Therefore, drying of the inner surface of the accommodation space 11 is reduced or prevented even at the position above the liquid level 1c, and thus the effect of maintaining the cooling performance at the second mount 32 has been suggested.

### Fourth Embodiment

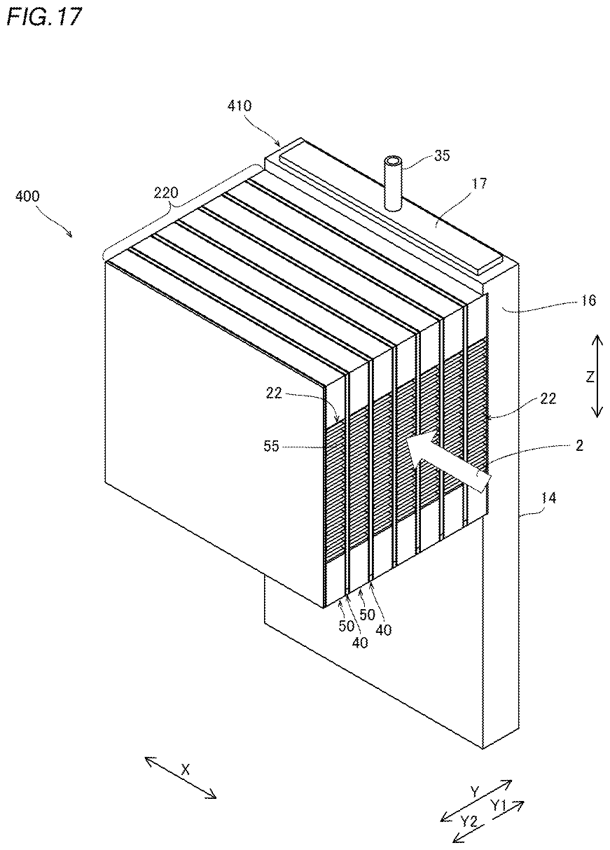

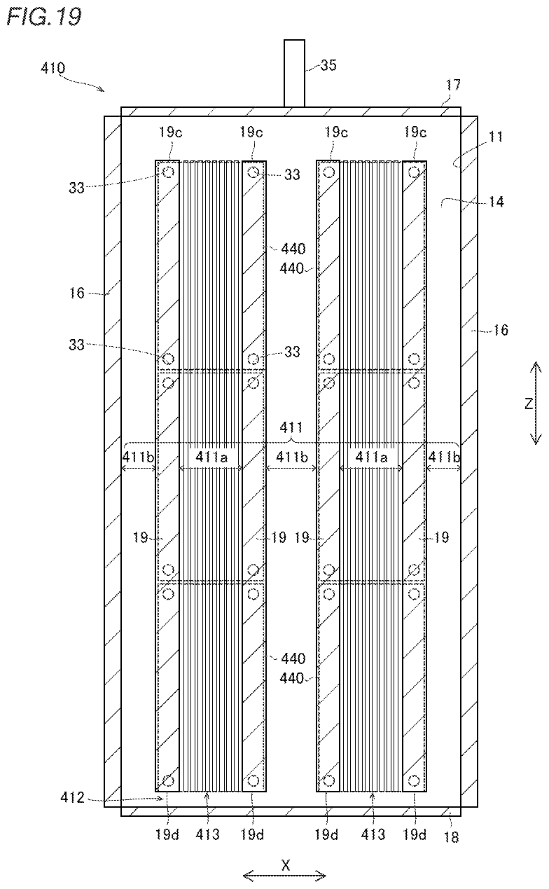

Referring to FIGS. 17 to 20, the configuration of a boiling cooler 400 (hereinafter referred to as a cooler 400) according to a fourth embodiment of the present invention is now described. In the fourth embodiment, first passage portions 411a (see FIG. 19) that communicate with refrigerant gas outlets 12 and second passage portions 411b (see FIG. 19) that communicate with refrigerant liquid inlets 13 are provided in an accommodation space 11 of a boiling part 410.

In the fourth embodiment, configurations other than the boiling part 410 are the same as those of the third embodiment.

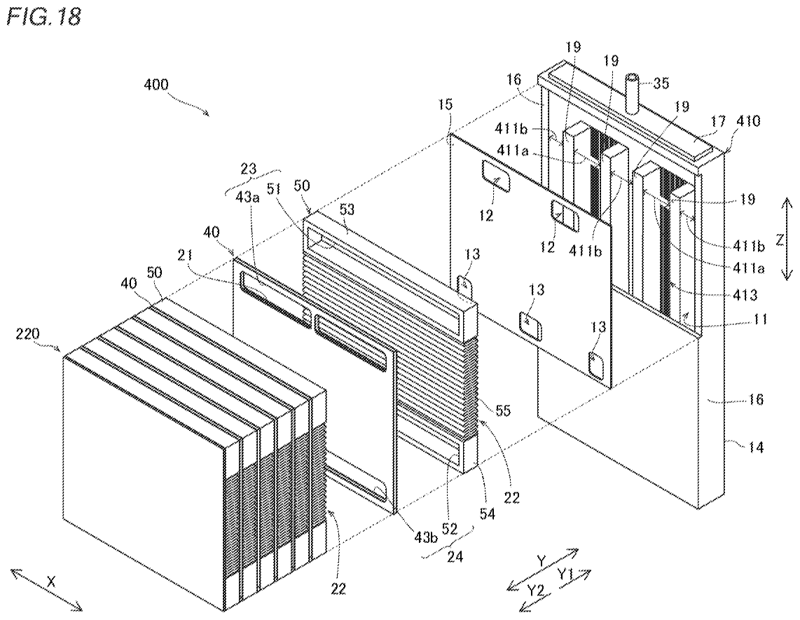

As shown in FIGS. 17 and 18, the cooler 400 according to the fourth embodiment includes the boiling part 410 and a condensing part 220. In the cooler 400 according to the fourth embodiment, as shown in FIG. 19, heat conductive portions 19 extend in a direction (Z direction) from the refrigerant liquid inlets 13 toward the refrigerant gas outlets 12 in the accommodation space 11, and partition the accommodation space 11 into a plurality of passage portions 411. The heat conductive portions 19 include partition walls in the accommodation space 11. Specifically, in the accommodation space 11, four heat conductive portions 19 are arranged at intervals in an X direction, and the accommodation space 11 is partitioned into five passage portions 411.

In the Z direction, the upper end 19c of each heat conductive portion 19 extends to the vicinity of the upper end of an arrangement region 440 of a heating element HS, and the lower end 19d of each heat conductive portion 19 extends to the vicinity of the lower end of an arrangement region 440 of a heating element HS. There is a gap between the upper end 19c of each heat conductive portion 19 and an upper wall 17, and upper portions of the five passage portions 411 communicate with each other. Furthermore, between the lower end 19d of each heat conductive portion 19 and a lower wall 18, there is a connection path 412 that allows lower portions of the five passage portions 411 to communicate with each other. The upper end 19c of each heat conductive portion 19 may contact the upper wall 17, and the upper portions of the five passage portions 411 may not communicate with each other.

The plurality of passage portions 411 include first passage portions 411a and second passage portions 411b. In FIG. 19, the five passage portions 411 include two first passage portions 411a and three second passage portions 411b. The two first passage portions 411a are arranged at an interval in the X direction, and the second passage portions 411b are arranged between the two first passage portions 411a and on both outer sides of the two first passage portions 411a. That is, the first passage portions 411a and the second passage portions 411b are arranged alternately in the X direction so as to be adjacent to each other with the heat conductive portion 19 interposed therebetween. Lower portions of the first passage portions 411a and lower portions of the second passage portions 411b communicate with each other as described above.

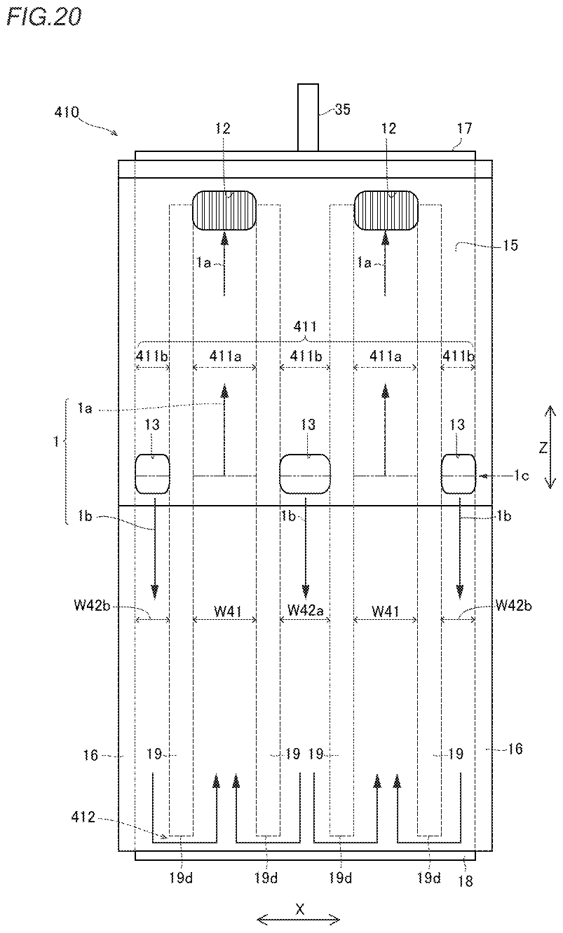

The two first passage portions 411a have the same shape. The first passage portions 411a are arranged at positions overlapping with the arrangement regions 440 of the heating elements HS via a first wall 14. In an example of FIG. 19, mounting holes 33 for mounting the heating element HS are provided in each of a pair of heat conductive portions 19 on both sides of the first passage portion 411a. The arrangement region 440 (broken line portion) of the heating element HS is a region straddling the first passage portion 411a and each of the pair of heat conductive portions 19 on both sides of the first passage portion 411a. The total width of the first passage portion 411a and the pair of heat conductive portions 19 on both sides of the first passage portion 411a corresponds to the width of the arrangement region 440 of the heating element HS. In the example of FIG. 19, three arrangement regions 440 are provided in the Z direction for one first passage portion 411a. Therefore, heat from the heating element HS is directly input to the first passage portion 411a and the heat conductive portions 19 on both sides thereof via the first wall 14. As described below, the first passage portions 411a communicate with the refrigerant gas outlets 12 (see FIG. 20) in the vicinity of their upper ends. A plurality of linear uneven portions 413 extending in the Z direction are provided on the inner surface of the first wall 14 in the first passage portion 411a. The uneven portions 413 increase a heat transfer area in the first passage portion 411a.

The three second passage portions 411b are arranged at positions (positions shifted from the arrangement regions 440) not overlapping with the arrangement regions 440 of the heating elements HS via the first wall 14. Therefore, the first passage portions 411a and the heat conductive portions 19 are interposed in a heat transfer path from the heating elements HS to the second passage portions 411b. Unlike the first passage portions 411a, the second passage portions 411b are not provided with uneven portions 413. The second passage portions 411b are adjacent to the first passage portions 411a and communicate with the refrigerant liquid inlets 13 (see FIG. 20).

As shown in FIG. 20, each of the first passage portions 411a has a width W41. The width W41 of each of the first passage portions 411a is larger than the widths W42a and W42b of the second passage portions 411b. The width W41 may be equal to the widths W42a and W42b or may be smaller than the widths W42a and W42b.

One second passage portion 411b at the center in the X direction has a width W42a. Each of the two second passage portions 411b on both sides in the X direction has a width W42b. Although the width W42a is larger than the width W42b, the width W42a and the width W42b may be the same, or the width W42a may be smaller.

As shown in FIG. 18, the refrigerant gas outlets 12 and the refrigerant liquid inlets 13 are openings formed in a second wall 15. The refrigerant gas outlets 12 are connected to the first passage portions 411a and are connected to a refrigerant gas distribution passage 23 (connection passages 51 and through-holes 43a) of the condensing part 220. The refrigerant liquid inlets 13 are connected to the second passage portions 411b and are connected to a refrigerant liquid collection passage 24 (connection passages 52 and through-holes 43b) of the condensing part 220.

As shown in FIG. 20, the refrigerant gas outlets 12 are provided at positions not opening to the second passage portions 411b but opening to the first passage portions 411a. A total of two refrigerant gas outlets 12 are provided, one for each of the two first passage portions 411a. Each refrigerant gas outlet 12 is provided at a position overlapping with the corresponding first passage portion 411a in a Y direction. In FIG. 20, the width of each of the refrigerant gas outlets 12 is substantially equal to the width W41 of the first passage portion 411a. The refrigerant gas outlets 12 are not provided at locations at which the three second passage portions 411b are provided. The refrigerant gas outlets 12 may open not only to the first passage portions 411a but also to the second passage portions 411b.

The refrigerant liquid inlets 13 are provided at positions not opening to the first passage portions 411a but opening to the second passage portions 411b. A total of three refrigerant liquid inlets 13 are provided, one for each of the three second passage portions 411b. Each refrigerant liquid inlet 13 is provided at a position overlapping with the corresponding second passage portion 411b in the Y direction. In FIG. 20, the width of each of the refrigerant liquid inlets 13 is substantially equal to the width (W42a or W42b) of the corresponding second passage portion 411a. The refrigerant liquid inlets 13 are not provided at locations at which the two first passage portions 411a are provided.

With such a configuration, in the fourth embodiment, the first passage portions 411a are configured as passages dedicated for a refrigerant gas 1a going from the boiling part 410 to the condensing part 220, and the second passage portions 411b are configured as passages dedicated for a refrigerant liquid 1b returning from the condensing part 220 to the boiling part 410.

In the first passage portions 411a provided directly below the arrangement regions 440, the refrigerant liquid 1b boils and becomes a refrigerant gas 1a due to heat input from the heating elements HS. The refrigerant gas 1a in the first passage portions 411a moves upward in the Z direction, flows into the condensing part 220 through the refrigerant gas outlets 12, and is cooled and condensed in the condensing part 220. A portion of the heat from the heating elements HS is also transferred to the second passage portions 411b, but most of the heat is transferred from the first wall 14 to the second wall 15 in the heat conductive portions 19 between the first passage portions 411a and the second passage portions 411b and is absorbed by an external fluid 2 (see FIG. 17) flowing through an external passage 22 (see FIG. 18) adjacent to the second wall 15. The remaining portion of the heat of the heating elements HS is transferred to the refrigerant liquid 1b in the second passage portions 411b, and may cause the refrigerant liquid 1b in the second passage portions 411b to boil.

The refrigerant liquid 1b condensed in the condensing part 220 flows into each refrigerant liquid inlet 13 due to the action of gravity. Therefore, the refrigerant liquid 1bflows to the second passage portions 411b of the boiling part 410 through the refrigerant liquid inlets 13 without directly flowing into the first passage portions 411a. The refrigerant liquid 1b that has flowed into the second passage portions 411b merges with the refrigerant liquid 1b stored in the lower portions of the second passage portions 411b. In an example of FIG. 20, the liquid level 1c of a refrigerant 1 is set at a height in the vicinity of intermediate positions of the refrigerant liquid inlets 13, but the liquid level 1c of the refrigerant 1 may be located above or below the refrigerant liquid inlets 13. The refrigerant liquid 1b that has been vaporized and decreased in the first passage portions 411a is replenished from the second passage portions 411b through the connection path 412 at the lower end of the boiling part 410. In this manner, the refrigerant 1 is circulated in the cooler 400.

Thus, in the fourth embodiment, a movement path of the refrigerant gas 1a going from the boiling part 410 to the condensing part 220 and a movement path of the refrigerant liquid 1b returning from the condensing part 220 to the boiling part 410 are connected to each other without overlapping. Therefore, especially at the refrigerant liquid inlets 13, the flow of the refrigerant gas 1a flowing upward in the Z direction and the flow of the refrigerant liquid 1bflowing downward in the Z direction do not collide with each other.

The remaining configurations of the fourth embodiment are similar to those of the third embodiment.

### Advantageous Effects of Fourth Embodiment

According to the fourth embodiment, similarly to the first embodiment, the boiling part 410 includes the accommodation space 11 to accommodate the refrigerant 1, the refrigerant gas outlets 12 connected to the accommodation space 11, and the refrigerant liquid inlets 13 connected to the accommodation space 11, and thus inhibition of movement of the refrigerant liquid 1b by the refrigerant gas 1a can be reduced or prevented. Furthermore, the boiling part 410 includes the first wall 14 to which the heating elements HS are mounted, the second wall 15 facing the first wall 14 via the accommodation space 11 and adjacent to the external passage 22, and the heat conductive portions 19 to connect the first wall 14 to the second wall 15 through the accommodation space 11, and thus even when the external fluid 2 is at a low temperature, a rapid decrease in cooling performance due to an increase in the amount of heat input can be reduced or prevented.

According to the fourth embodiment, as described above, the heat conductive portions 19 extend in the Z direction from the refrigerant liquid inlets 13 toward the refrigerant gas outlets 12 in the accommodation space 11, and are operable to partition the accommodation space 11 into the plurality of passage portions 411. The plurality of passage portions 411 include the first passage portions 411a arranged at the positions overlapping with the arrangement regions 440 of the heating elements HS via the first wall 14 and communicating with the refrigerant gas outlets 12, and the second passage portions 411b adjacent to the first passage portions 411a and communicating with the refrigerant liquid inlets 13, and the lower portions of the first passage portions 411a and the lower portions of the second passage portions 411b communicate with each other. Accordingly, the first passage portions 411athrough which the refrigerant gas 1a going to the condensing part 220 flows and the second passage portions 411b through which the refrigerant liquid 1b returning from the condensing part 220 to the boiling part 410 flows can be separately provided in the accommodation space 11. When the refrigerant liquid 1b is returned to the middle of the movement path of the refrigerant gas 1a, the circulation of the refrigerant 1 may be hindered by collision between the flow of the refrigerant gas 1a and the flow of the refrigerant liquid 1b. In this regard, according to the above configuration, the movement path (first passage portions 411a) of the refrigerant gas 1a and the movement path (second passage portions 411b) of the refrigerant liquid 1b can be made separate, and thus the refrigerant 1 can be circulated smoothly. Consequently, the heat exchange efficiency can be improved.

According to the fourth embodiment, as described above, the refrigerant liquid inlets 13 are provided at the positions not opening to the first passage portions 411a but opening to the second passage portions 411b. Accordingly, the second passage portions 411b can be configured as passages dedicated for the refrigerant liquid 1b returning from the condensing part 220. The movement path (first passage portions 411a) of the refrigerant gas 1a and the movement path (second passage portions 411b) of the refrigerant liquid 1b in the boiling part 410 can be separated, and thus collision between the flow of the refrigerant gas 1a and the flow of the refrigerant liquid 1b can be prevented.

The remaining advantageous effects of the fourth embodiment are similar to those of the third embodiment.

### Fifth Embodiment

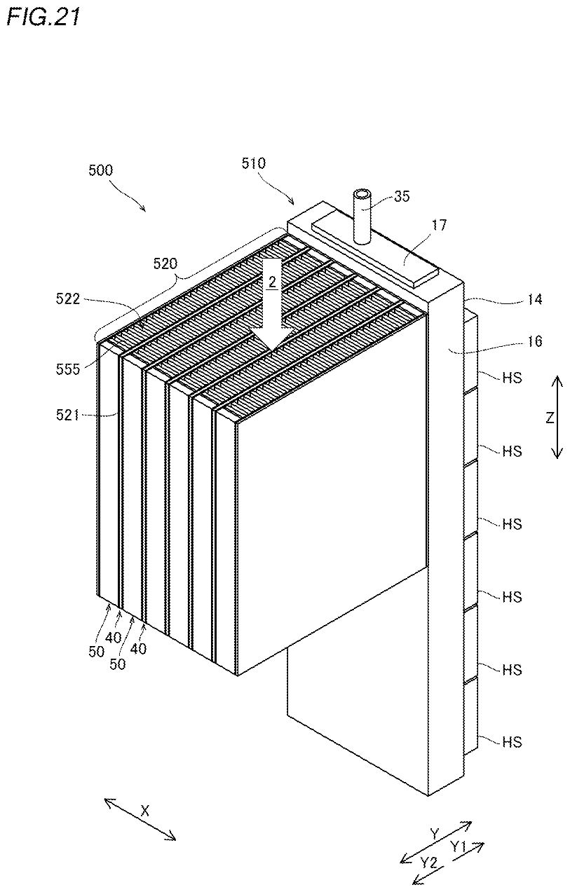

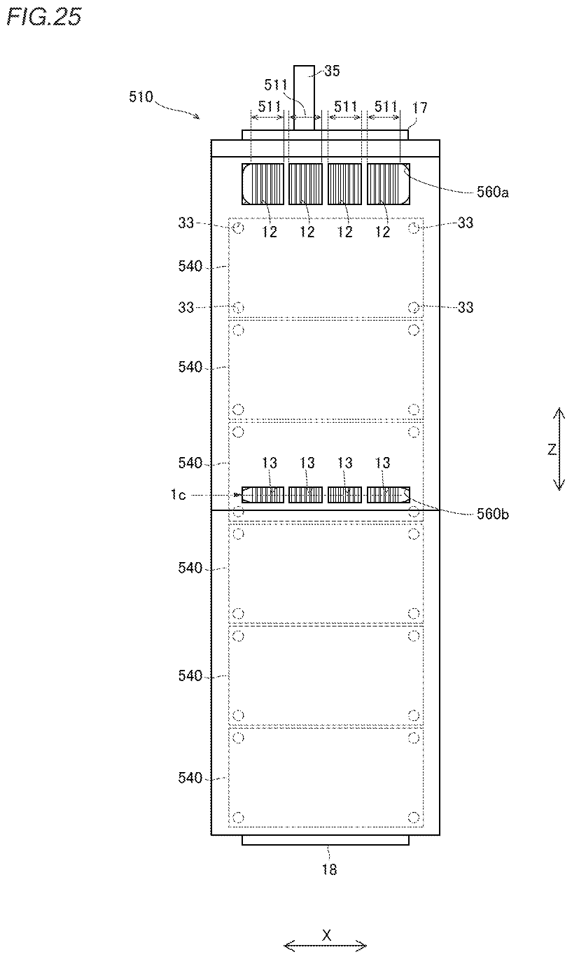

Referring to FIGS. 21 and 25, the configuration of a boiling cooler 500 (hereinafter referred to as a cooler 500) according to a fifth embodiment of the present invention is now described. In the fifth embodiment, the directions of refrigerant passages 521 and external passages 522 in a condensing part 520 are different from those of the first to fourth embodiments.

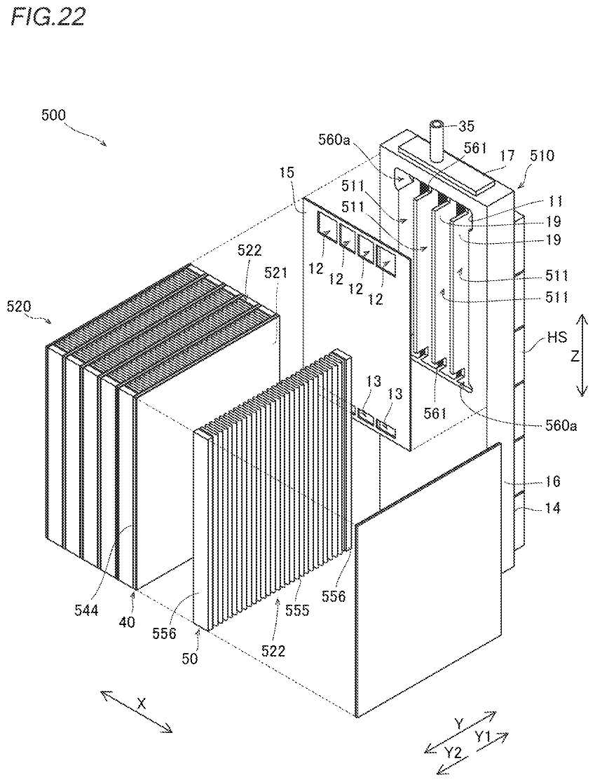

As shown in FIG. 21, the cooler 500 according to the fifth embodiment includes a boiling part 510 and the condensing part 520. In the cooler 500, the condensing part 520 includes the external passages 522 extending along a Z direction. That is, in the first to fourth embodiments, the external passages are provided along an X-Z plane and passes through the condensing parts in an X direction. On the other hand, in the fifth embodiment, each external passage 522 is provided along a Y-Z plane and passes through the condensing part 520 in the Z direction. The external passages 522 allow an external fluid 2 to flow therethrough in the Z direction. As shown in FIG. 22, both ends of corrugated fins 555 of the external passages 522 in a Y direction are defined by side bars 556.

Along with this, each refrigerant passage 521 of the condensing part 520 is provided along the Y-Z plane, receives a refrigerant gas 1a from an upper portion of the end face in a Y1 direction, and sends a refrigerant liquid 1b obtained by condensing the refrigerant gas 1a from a lower portion of the end face in the Y1 direction to the boiling part 510. The external passages 522 (second layers 50) and the refrigerant passages 521 (first layers 40) are stacked in the X direction. In the first to fourth embodiments, each refrigerant passage communicates with the boiling part via the refrigerant gas distribution passage 23 (see FIG. 18) and the refrigerant liquid collection passage 24 (see FIG. 18) provided in the condensing part, but in the fifth embodiment, these refrigerant gas distribution passage 23 and refrigerant liquid collection passage 24 are not provided in the condensing part 520.

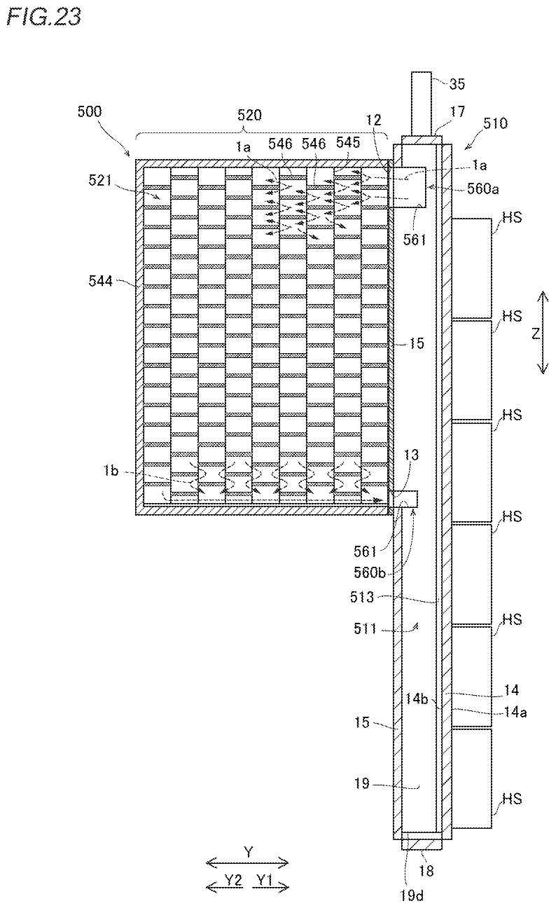

As shown in FIG. 23, each refrigerant passage 521 is a space surrounded by a peripheral wall 544 on the Y2 side and both upper and lower sides (both sides in a Z direction), and of which the end face on the Y1 side is covered with a second wall 15. A serrate (offset) corrugated fin 545 is provided inside the refrigerant passage 521. In the serrate corrugated fin 545, fin portions 546 along the Y direction are arranged at equal pitches in the Z direction, and the positions of the fin portions 546 in the Z direction are shifted by half a pitch for each row along the Z direction. A refrigerant 1 (refrigerant gas 1a and refrigerant liquid 1b) can pass through gaps between these fin portions 546. The refrigerant passages 521 communicate with refrigerant gas outlets 12 of the boiling part 510 (second wall 15) at an upper portion of the Y1 side end, and communicate with refrigerant liquid inlets 13 of the boiling part 510 at a lower portion of the Y1 side end.

In the fifth embodiment, a refrigerant gas distribution passage 23 (see FIG. 18) and a refrigerant liquid collection passage 24 (see FIG. 18) are not provided in the condensing part 520, and thus the refrigerant passages 521 and the external passages 522 can be increased in size, and the refrigerant condensing capability (heat release capability) of the condensing part 520 can be increased.

As shown in FIG. 22, the second wall 15 of the boiling part 510 includes the refrigerant gas outlets 12 connected to a plurality of refrigerant passages 521. In an example of FIG. 22, five refrigerant passages 521 are provided in the condensing part 520, and four refrigerant gas outlets 12 are aligned in the X direction so as to communicate with the refrigerant passages 521.

Similarly, the second wall 15 of the boiling part 510 includes the refrigerant liquid inlets 13 connected to the plurality of refrigerant passages 521. In the example of FIG. 22, four refrigerant liquid inlets 13 are aligned in the X direction so as to communicate with the refrigerant passages 521. The four refrigerant gas outlets 12 and the four refrigerant liquid inlets 13 may be connected to each other to configure one refrigerant gas outlet 12 and one refrigerant liquid inlet 13 extending in the X direction so as to be connected to each refrigerant passage 521.

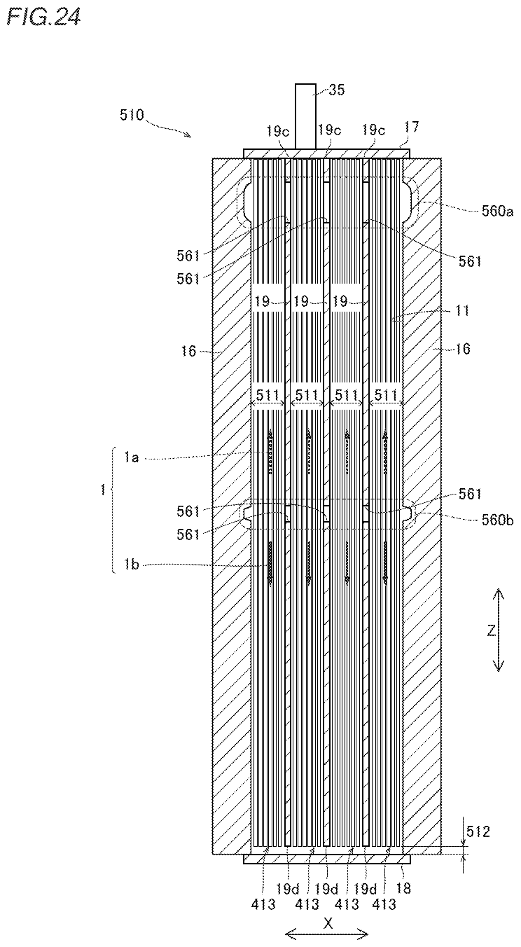

As shown in FIG. 24, heat conductive portions 19 extend in a direction (Z direction) from the refrigerant liquid inlets 13 toward the refrigerant gas outlets 12 in an accommodation space 11, and partition the accommodation space 11 into a plurality of passage portions 511. The heat conductive portions 19 include partition walls in the accommodation space 11. Specifically, in the accommodation space 11, three heat conductive portions 19 are arranged at intervals in the X direction, and the accommodation space 11 is partitioned into four passage portions 511.

In the Z direction, the upper end 19c of each heat conductive portion 19 contacts an upper wall 17, and the lower end 19d of each heat conductive portion 19 extends to the vicinity of a lower wall 18. A space between the lower end 19d of each heat conductive portion 19 and the lower wall 18 serves as a connection path 512 that allows lower portions of the four passage portions 511 to communicate with each other. A plurality of linear uneven portions 513 extending in the Z direction are provided on the inner surface of a first wall 14 in each passage portion 511. As shown in FIG. 25, arrangement regions 540 of heating elements HS mounted to mounting holes 33 extend in the X direction and straddle the passage portions 511.

As shown in FIG. 24, the cooler 500 according to the fifth embodiment further includes, in portions of the accommodation space 11 of the boiling part 510, distribution portions 560a and 560b to allow the plurality of refrigerant passages 521 and the plurality of passage portions 511 to communicate with each other. Specifically, the distribution portion 560a connected to the refrigerant gas outlets 12 and the distribution portion 560b connected to the refrigerant liquid inlets 13 are provided in the accommodation space 11.

The distribution portion 560a is provided adjacent to the refrigerant gas outlets 12 (see FIG. 22) in the Y direction. The distribution portion 560a is a space passing through portions of the heat conductive portions 19 formed as partition walls in the X direction. That is, the distribution portion 560a includes notches 561 formed in the portions of the heat conductive portions 19, and the notches 561 provided in the three heat conductive portions 19, respectively, are aligned in the X direction. Consequently, the distribution portion 560a is formed, which is a communication space extending in the X direction in the accommodation space 11 so as to straddle the four passage portions 511. The four refrigerant gas outlets 12 (see FIG. 25) are provided corresponding to the four passage portions 511, and the four passage portions 511 communicate with each other at the distribution portion 560. Therefore, each refrigerant passage 521 of the condensing part 520 communicates with all (four) passage portions 511 via one of the refrigerant gas outlets 12 and the distribution portion 560a.

The distribution portion 560b is provided adjacent to the refrigerant liquid inlets 13 (see FIG. 22) in the Y direction. The distribution portion 560b has a similar structure to the distribution portion 560a, and includes notches 561 formed in portions of the heat conductive portions 19. Thus, the distribution portion 560b is formed to extend in the X direction in the accommodation space 11 so as to straddle the four passage portions 511. The four refrigerant liquid inlets 13 (see FIG. 25) are provided corresponding to the four passage portions 511, and the four passage portions 511 communicate with each other at the distribution portion 560b. Therefore, each refrigerant passage 521 of the condensing part 520 communicates with all (four) passage portions 511 via one of the refrigerant liquid inlets 13 and the distribution portion 560b. The liquid level 1c of the refrigerant 1 is set in the vicinity of an intermediate position of the distribution portion 560b (refrigerant liquid inlets 13).

With such a configuration, in the fifth embodiment, the refrigerant passages 521 are directly connected to the refrigerant gas outlets 12 and the refrigerant liquid inlets 13 of the boiling part 510, and the distribution portions 560a and 560b are provided in the accommodation space 11 of the boiling part 510 to allow the refrigerant passages 521 and the passage portions 511 to communicate with each other.

In the passage portions 511, the refrigerant liquid 1b boils and becomes a refrigerant gas 1a due to heat input from the heating elements HS. The refrigerant gas 1a in the passage portions 511 moves upward in the Z direction and merges at the distribution portion 560a. The refrigerant gas 1a that has merged at the distribution portion 560a flows into the refrigerant passages 521 of the condensing part 520 through the refrigerant gas outlets 12 (see FIG. 25). The refrigerant gas 1a merges at the distribution portion 560a, and thus even when the flow rate (amount of generation) of the refrigerant gas 1a in the individual passage portions 511 varies, the amount of refrigerant gas 1a flowing into each refrigerant passage 521 can be made uniform.

The refrigerant gas 1a is cooled and condensed in each refrigerant passage 521. Due to the action of gravity, the condensed refrigerant liquid 1b flows from one of the refrigerant liquid inlets 13 (see FIG. 25) to the distribution portion 560b and merges. Although the refrigerant liquid 1b flows into the middle of the flow of the refrigerant gas 1a moving upward through the passage portions 511, the distribution portion 560b is a wide space in which the passage portions 511 communicate with each other, and thus obstruction of the flow of the refrigerant gas 1a by the flow of the refrigerant liquid 1b is reduced or prevented.

The refrigerant liquid 1b that has been vaporized and decreased in each passage portion 511 can be replenished from another passage portion 511 through the distribution portion 560b or the lower connection path 512, and thus the amount of refrigerant liquid 1b stored in each passage portion 511 is made uniform. In this manner, the refrigerant 1 is circulated in the cooler 500.

The remaining configurations of the fifth embodiment are similar to those of the third embodiment.

### Advantageous Effects of Fifth Embodiment

According to the fifth embodiment, similarly to the first embodiment, the boiling part 510 includes the accommodation space 11 to accommodate the refrigerant 1, the refrigerant gas outlets 12 connected to the accommodation space 11, and the refrigerant liquid inlets 13 connected to the accommodation space 11, and thus inhibition of movement of the refrigerant liquid 1b by the refrigerant gas 1a can be reduced or prevented. Furthermore, the boiling part 510 includes the first wall 14 to which the heating elements HS are mounted, the second wall 15 facing the first wall 14 via the accommodation space 11 and adjacent to the external passage 22, and the heat conductive portions 19 to connect the first wall 14 to the second wall 15 through the accommodation space 11, and thus even when the external fluid 2 is at a low temperature, a rapid decrease in cooling performance due to an increase in the amount of heat input can be reduced or prevented.

According to the fifth embodiment, as described above, the condensing part 520 includes the plurality of refrigerant passages 521, the heat conductive portions 19 extend in the Z direction from the refrigerant liquid inlets 13 toward the refrigerant gas outlets 12 in the accommodation space 11, and are operable to partition the accommodation space 11 into the plurality of passage portions 511, and the boiling cooler 500 further includes, in the portion of the accommodation space 11 of the boiling part 510, the distribution portion 560a to allow the plurality of refrigerant passages 521 and the plurality of passage portions 511 to communicate with each other. Accordingly, even when the accommodation space 11 is partitioned into the plurality of passage portions 511, the refrigerant gas 1a can flow between each of the plurality of passage portions 511 and each of the plurality of refrigerant passages 521 in the condensing part 520 by providing the distribution portion 560a. Consequently, even when there is a difference in the flow rate of the refrigerant gas 1a between the plurality of passage portions 511, for example, variations in the flow rate of the refrigerant gas 1a to the plurality of refrigerant passages 521 can be reduced or prevented by interposing the distribution portion 560. Therefore, variations in heat exchange performance during operation of the boiling cooler 500 can be effectively reduced or prevented.

According to the fifth embodiment, the distribution portion 560b is provided. Accordingly, a wide space (distribution portion 560b) can be provided at a location at which the flow of the refrigerant gas 1a and the flow of the refrigerant liquid 1b collide with each other to allow the plurality of passage portions 511 to communicate with each other. Therefore, even when the refrigerant liquid 1b flows into the passage portions 511 through the refrigerant liquid inlets 13, a sufficient volume is ensured, and thus obstruction of the flow of the refrigerant gas 1a by the flow of the refrigerant liquid 1b can be reduced or prevented. Consequently, the refrigerant 1 can be circulated smoothly, and thus the heat exchange efficiency can be improved.

According to the fifth embodiment, the distribution portion 560a and the distribution portion 560b are provided. Accordingly, a refrigerant gas distribution passage 23 (see FIG. 18) and a refrigerant liquid collection passage 24 (see FIG. 18) are not provided in the condensing part 520, and thus the refrigerant passages 521 and the external passages 522 can be increased in size, and the refrigerant condensing capability (heat release capability) of the condensing part 520 can be increased.

The remaining advantageous effects of the fifth embodiment are similar to those of the third embodiment.

### Sixth Embodiment

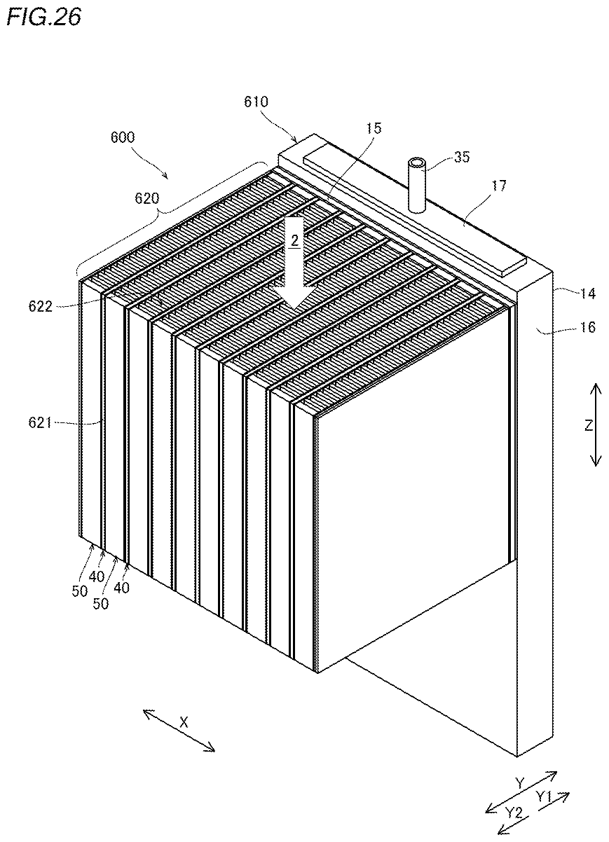

Referring to FIGS. 26 to 29, the configuration of a boiling cooler 600 (hereinafter referred to as a cooler 600) according to a sixth embodiment of the present invention is now described. In the sixth embodiment, the configuration of the boiling part 410 shown in the fourth embodiment and the configuration of the condensing part 520 shown in the fifth embodiment are combined.

As shown in FIG. 26, the cooler 600 according to the sixth embodiment includes a boiling part 610 and a condensing part 620.

The condensing part 620 has the same configuration as that of the fifth embodiment. External passages 622 pass through the condensing part 620 in a Z direction and allow an external fluid 2 to flow therethrough in the Z direction. Refrigerant passages 621 of the condensing part 620 are provided along a Y-Z plane, receive a refrigerant gas 1a from upper portions of the end faces in a Y1 direction, and send a refrigerant liquid 1b obtained by condensing the refrigerant gas 1a from lower portions of the end faces in the Y1 direction to the boiling part 610.

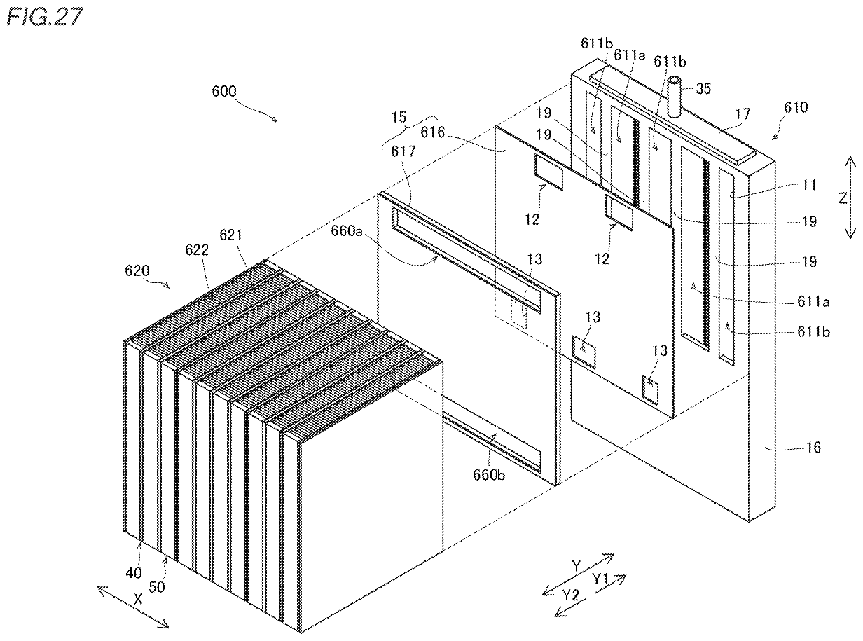

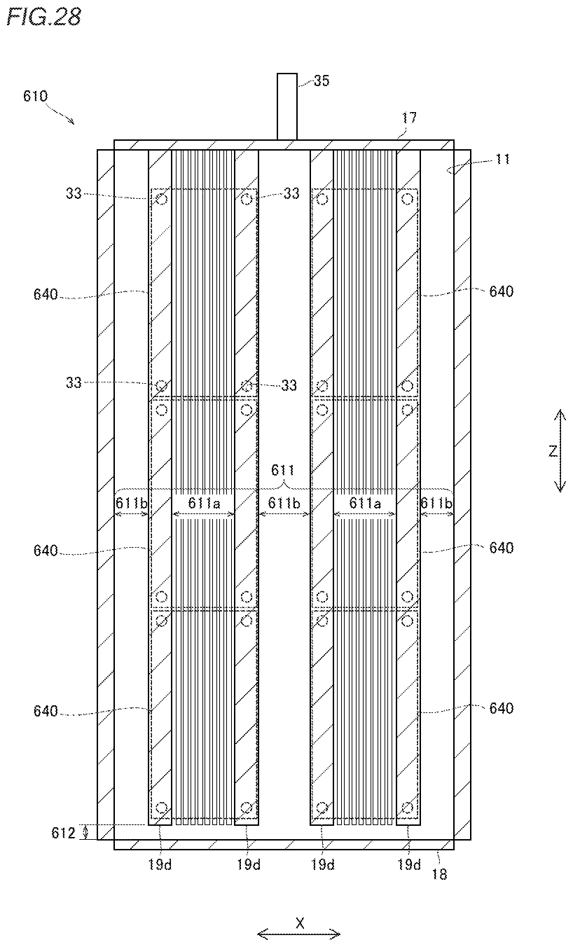

The boiling part 610 has a similar configuration as that of the fourth embodiment. That is, as shown in FIGS. 27 and 28, heat conductive portions 19 extend in a direction from refrigerant liquid inlets 13 toward refrigerant gas outlets 12 in an accommodation space 11, and partition the accommodation space 11 into a plurality of passage portions 611. Specifically, four heat conductive portions 19 partition the accommodation space 11 into five passage portions 611. The plurality of passage portions 611 include first passage portions 611a and second passage portions 611b. In an example of FIG. 28, the five passage portions 611 include two first passage portions 611a and three second passage portions 611b.

The first passage portions 611a are arranged at positions overlapping with arrangement regions 640 of heating elements HS via a first wall 14, and communicate with the refrigerant gas outlets 12 (see FIG. 27) in the vicinity of their upper ends. The second passage portions 611b are arranged at positions (positions shifted from the arrangement regions 640) not overlapping with the arrangement regions 640 of the heating elements HS via the first wall 14, and communicate with the refrigerant liquid inlets 13 (see FIG. 27). Lower portions of the first passage portions 611a and lower portions of the second passage portions 611b communicate with each other through a connection path 612.

As shown in FIG. 27, a second wall 15 of the boiling part 610 includes two refrigerant gas outlets 12 and three refrigerant liquid inlets 13. The two refrigerant gas outlets 12 are provided on a one-to-one basis with the two first passage portions 611a and open to the corresponding first passage portions 611a, while the two refrigerant gas outlets 12 do not open to any of the second passage portions 611b. The two refrigerant gas outlets 12 are arranged side by side in an X direction at the same position in the Z direction. The three refrigerant liquid inlets 13 are provided on a one-to-one basis with the three second passage portions 611b and open to the corresponding second passage portions 611b, while the three refrigerant gas outlets 12 do not open to any of the first passage portions 611a. The three refrigerant liquid inlets 13 are arranged side by side in the X direction at the same position in the Z direction.

The cooler 600 according to the sixth embodiment further includes distribution portions 660a and 660b that are provided in the second wall 15 of the boiling part 610 and allow a plurality of refrigerant passages 621 and the plurality of passage portions 611 to communicate with each other. That is, in the fifth embodiment, the distribution portions 560a and 560b are provided in the accommodation space 11 of the boiling part 510, but in this sixth embodiment, the distribution portions 660a and 660b are provided in the second wall 15.

Specifically, the second wall 15 includes a stacked body of a first plate 616 in which the refrigerant gas outlets 12 and the refrigerant liquid inlets 13 are provided, and a second plate 617 in which the distribution portions 660a and 660b are provided.

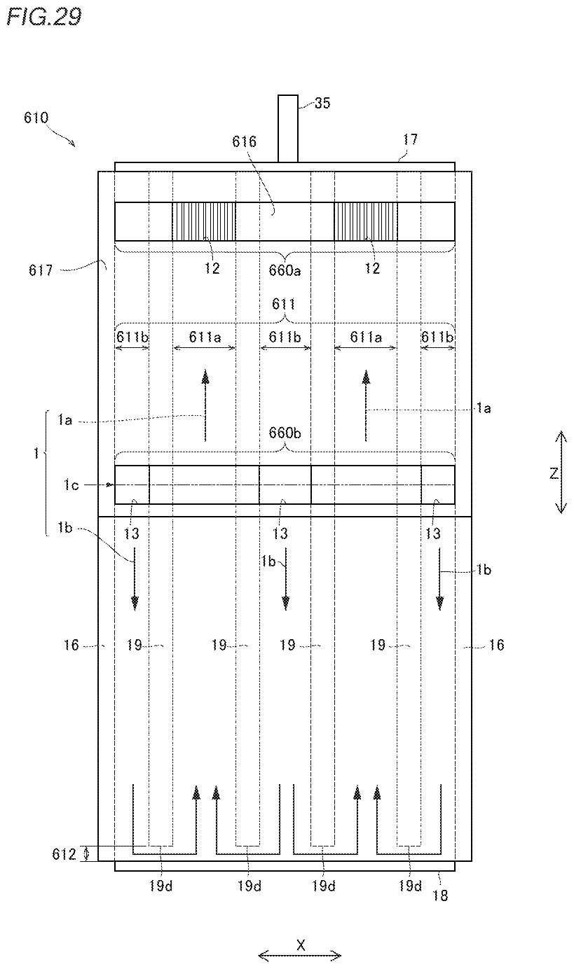

The distribution portion 660a is formed into a rectangular shape extending in the X direction so as to encompass the two refrigerant gas outlets 12, and passes through the second plate 617 in the thickness direction. Therefore, as shown in FIG. 29, one distribution portion 660a communicates with both of the two refrigerant gas outlets 12. An opening of the distribution portion 660a on the Y2 side communicates with upper portions of the refrigerant passages 621 arranged in the X direction in the condensing part 620.

Therefore, in FIG. 27, the refrigerant passages 621 of the condensing part 620 communicate with the two first passage portions 611a via the distribution portion 660a and the refrigerant gas outlets 12.

The distribution portion 660b is formed into a rectangular shape extending in the X direction so as to encompass the three refrigerant liquid inlets 13, and passes through the second plate 617 in the thickness direction. Therefore, as shown in FIG. 29, one distribution portion 660b communicates with each of the three refrigerant liquid inlets 13. An opening of the distribution portion 660b on the Y2 side communicates with lower portions of the refrigerant passages 621 arranged in the X direction in the condensing part 620.

Therefore, in FIG. 27, the refrigerant passages 621 of the condensing part 620 communicate with the three second passage portions 611b via the distribution portion 660b and the refrigerant liquid inlets 13.

The thickness of the second plate 617 provided with the distribution portions 660a and 660b is larger than the thickness of the first plate 616. Therefore, the distribution portions 660a and 660b are spaces having a volume corresponding to the thickness of the second plate 617. The volume of the distribution portion 660a is increased such that even when the flow rate (amount of generation) of the refrigerant gas 1a in the two first passage portions 611a varies, variations in the flow rate of the refrigerant gas 1a flowing to the refrigerant passages 621 can be reduced or prevented by merging the refrigerant gas 1a from the two first passage portions 611a at the distribution portion 660a and temporarily storing the refrigerant gas 1a corresponding to the volume.

In FIG. 29, in the first passage portions 611a, the refrigerant liquid 1b boils and becomes a refrigerant gas 1a due to heat input from the heating elements HS. The refrigerant gas 1a in the first passage portions 611a moves upward in the Z direction and flows into the distribution portion 660a through the refrigerant gas outlets 12. After the refrigerant gas 1a merges at the distribution portion 660a, the refrigerant gas 1a flows into each refrigerant passage 621 of the condensing part 620, and is cooled and condensed in each refrigerant passage 621.

The refrigerant liquid 1b condensed in each refrigerant passage 621 flows from each refrigerant passage 621 into the distribution portion 660b due to the action of gravity. The refrigerant liquid 1b flows to the second passage portions 611b of the boiling part 610 through the refrigerant liquid inlets 13 after merging at the distribution portion 660b. Consequently, the refrigerant liquid 1b that has flowed into the second passage portions 611b merges with the refrigerant liquid 1b stored in the lower portions of the second passage portions 611b. The liquid level 1c of a refrigerant 1 is set at a height in the vicinity of intermediate positions of the refrigerant liquid inlets 13. The refrigerant liquid 1b that has been vaporized and decreased in the first passage portions 611a is replenished from the second passage portions 611b through the lower connection path 612 (see FIG. 28). In this manner, the refrigerant 1 is circulated in the cooler 600.

The remaining configurations of the sixth embodiment are similar to those of the fifth embodiment.

### Advantageous Effects of Sixth Embodiment

According to the sixth embodiment, similarly to the first embodiment, the boiling part 610 includes the accommodation space 11 to accommodate the refrigerant 1, the refrigerant gas outlets 12 connected to the accommodation space 11, and the refrigerant liquid inlets 13 connected to the accommodation space 11, and thus inhibition of movement of the refrigerant liquid 1b by the refrigerant gas 1a can be reduced or prevented. Furthermore, the boiling part 610 includes the first wall 14 to which the heating elements HS are mounted, the second wall 15 facing the first wall 14 via the accommodation space 11 and adjacent to the external passage 622, and the heat conductive portions 19 to connect the first wall 14 to the second wall 15 through the accommodation space 11, and thus even when the external fluid 2 is at a low temperature, a rapid decrease in cooling performance due to an increase in the amount of heat input can be reduced or prevented.

According to the sixth embodiment, similarly to the fourth embodiment, the heat conductive portions 19 partition the accommodation space 11 into the first passage portions 611a that communicate with the refrigerant gas outlets 12 and the second passage portions 611b that communicate with the refrigerant liquid inlets 13, and thus the circulation of the refrigerant 1 is not hindered by collision between the flow of the refrigerant gas 1a and the flow of the refrigerant liquid 1b, and the refrigerant 1 can be circulated smoothly. Consequently, the heat exchange efficiency can be improved.

According to the sixth embodiment, as described above, the boiling cooler 600 includes, in the second wall 15 of the boiling part 610, the distribution portion 660a to allow the plurality of refrigerant passages 621 and the plurality of passage portions 611 to communicate with each other. Accordingly, even when there is a difference in the flow rate of the refrigerant gas 1a between the first passage portions 611a, variations in the flow rate of the refrigerant gas 1a to the plurality of refrigerant passages 621 can be reduced or prevented by interposing the distribution portion 660a. Consequently, variations in heat exchange performance during operation of the boiling cooler 600 can be effectively reduced or prevented.

The remaining advantageous effects of the sixth embodiment are similar to those of the fifth embodiment.

### Seventh Embodiment

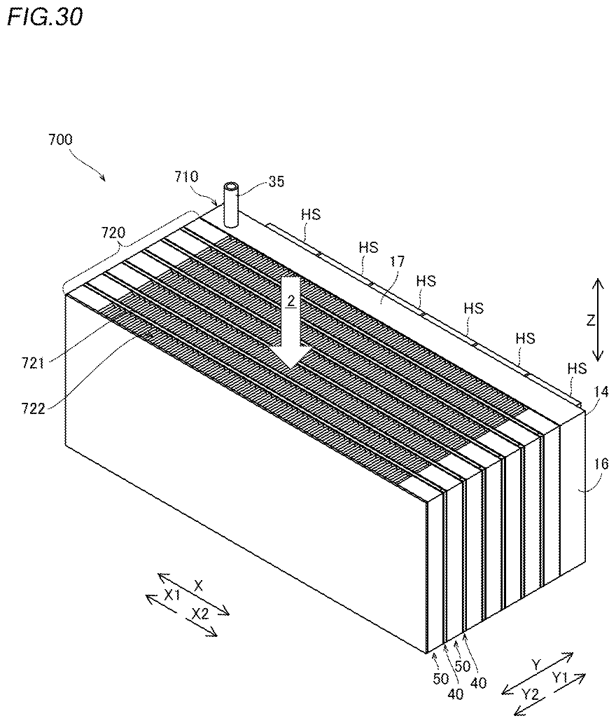

Referring to FIGS. 30 to 32, the configuration of a boiling cooler 700 (hereinafter referred to as a cooler 700) according to a seventh embodiment of the present invention is now described. In the sixth embodiment, an example of the cooler 600 has been shown in which the external passages 622 extending in the Z direction are provided in the condensing part 620, and the boiling part 610 and the condensing part 620 are stacked in the Y direction, while the first layers 40 (refrigerant passages 621) and the second layers 50 (external passages 622) in the condensing part 620 are stacked in the X direction. In this seventh embodiment, external passages 722 extending in a Z direction are provided, and a direction in which a boiling part 710 and a condensing part 720 are stacked matches a direction in which first layers 40 (refrigerant passages 721) and second layers 50 (external passages 722) are stacked in the condensing part 720.

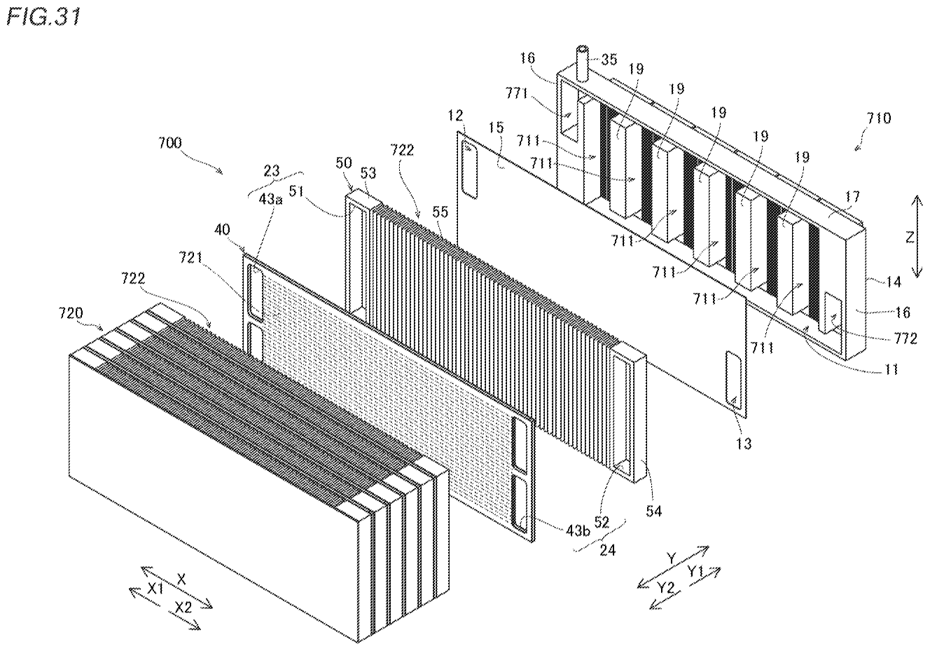

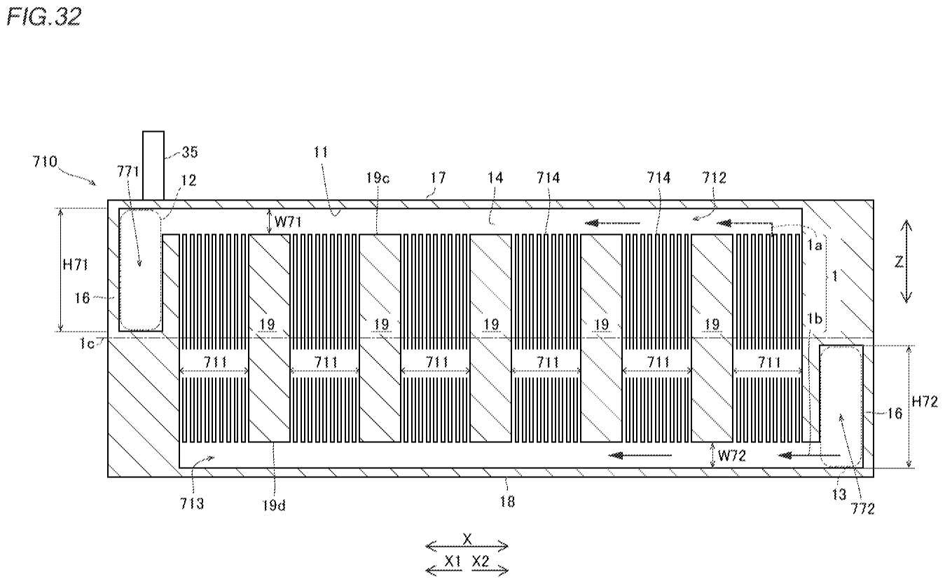

As shown in FIG. 30, in the cooler 700 according to the seventh embodiment, similarly to the cooler 600 according to the sixth embodiment, the condensing part 720 includes the external passages 722 that pass through the condensing part 720 in the Z direction and allow an external fluid 2 to flow therethrough in the Z direction. In the cooler 700 according to the seventh embodiment, the boiling part 710, and the first layers 40 (refrigerant passages 721) and the second layers 50 (external passages 722) in the condensing part 720 are stacked in a Y direction. That is, as shown in FIG. 31, the boiling part 710 and components (the first layers 40 and the second layers 50) of the condensing part 720 are stacked in a single direction (Y direction). Therefore, in the cooler 700 according to the seventh embodiment, the components of the condensing part 720 can be joined together by brazing an assembly in which the boiling part 710 and the components of the condensing part 720 are stacked when the cooler 700 is manufactured. That is, the seventh embodiment shows the cooler 700 having a structure that can be manufactured in a single brazing step.

Although the overall cooler 700 according to the seventh embodiment has a horizontally elongated shape extending in an X direction, it may have a vertically elongated shape extending in the Z direction, similarly to the first to sixth embodiments.

The refrigerant passages 721 of the condensing part 720 are provided along an X-Z plane, and as shown in FIG. 31, the refrigerant passages 721 receive a refrigerant gas 1a from a first end side in an X1 direction, allow the refrigerant gas 1a to flow therethrough toward a second end side in an X2 direction, and send a refrigerant liquid 1b obtained by condensing the refrigerant gas 1a from the second end side in the X2 direction to the boiling part 710. In FIG. 31, the refrigerant passages 721 are shown by broken lines.

The boiling part 710 includes an accommodation space 11 extending in the X direction. As shown in FIG. 32, the accommodation space 11 includes, in an upper portion thereof in the Z direction on the first end side in the X1 direction, an outlet-side accommodation portion 771 that communicates with a refrigerant gas outlet 12. The accommodation space 11 includes, in a lower portion thereof in the Z direction on the second end side in the X2 direction, an inlet-side accommodation portion 772 that communicates with a refrigerant liquid inlet 13.

Heat conductive portions 19 extend in the Z direction in the accommodation space 11 and partition the accommodation space 11 into a plurality of passage portions 711. Specifically, in the accommodation space 11, five heat conductive portions 19 are arranged side by side in the X direction between the outlet-side accommodation portion 771 and the inlet-side accommodation portion 772, and partition the accommodation space 11 into six passage portions 711.

In the Z direction, the upper ends 19c of the heat conductive portions 19 extend to the vicinity of an upper wall 17, and the lower ends 19d of the heat conductive portions 19 extend to the vicinity of a lower wall 18. An upper connection path 712 extending in the X direction and allowing the six passage portions 711 to communicate with the outlet-side accommodation portion 771 is provided between the upper ends 19c of the heat conductive portions 19 and the upper wall 17. A lower connection path 713 extending in the X direction and allowing the six passage portions 711 to communicate with the inlet-side accommodation portion 772 is provided between the lower ends 19d of the heat conductive portions 19 and the lower wall 18. The liquid level 1c of a refrigerant 1 is set in the vicinity of intermediate positions of the passage portions 711, for example.

The Z-direction dimension H71 of the outlet-side accommodation portion 771 is larger than the Z-direction width W71 of the upper connection path 712. The Z-direction dimension H72 of the inlet-side accommodation portion 772 is larger than the width W72 of the lower connection path 713. The Z-direction dimension H71 may be equal to or less than the width W71, and the Z-direction dimension H72 may be equal to or less than the width W72.

A plurality of linear uneven portions 714 extending in the Z direction are provided on the inner surface of a first wall 14 in the passage portions 711. The uneven portions 714 increase the heat transfer areas of the passage portions 711.

As shown in FIG. 31, a second wall 15 of the boiling part 710 includes one refrigerant gas outlet 12 and one refrigerant liquid inlet 13. The refrigerant gas outlet 12 is arranged at an end in the X1 direction in an upper portion of the second wall 15 in the Z direction, overlapping with the outlet-side accommodation portion 771 in the Y direction. The refrigerant gas outlet 12 communicates with the refrigerant passages 721 via a refrigerant gas distribution passage 23 arranged at a first end of the condensing part 720 in the X1 direction.

The refrigerant liquid inlet 13 is arranged at an end in the X2 direction in a lower portion of the second wall 15 in the Z direction, overlapping with the inlet-side accommodation portion 772 in the Y direction. The refrigerant liquid inlet 13 communicates with the refrigerant passages 721 via a refrigerant liquid collection passage 24 arranged at a second end of the condensing part 720 in the X2 direction.

In the passage portions 711 shown in FIG. 32, the refrigerant liquid 1b boils and becomes a refrigerant gas 1adue to heat input from heating elements HS. The refrigerant gas 1a in the passage portions 711 moves upward in the Z direction, flows into the upper connection path 712, flows in the X1 direction, and reaches the outlet-side accommodation portion 771. The refrigerant gas 1a flows into the refrigerant gas distribution passage 23 of the condensing part 720 from the outlet-side accommodation portion 771 via the refrigerant gas outlet 12. The outlet-side accommodation portion 771 has a larger space in the Z direction than the upper connection path 712, and thus obstruction of the flow of the refrigerant gas 1a flowing out from the upper connection path 712 is reduced or prevented. Consequently, the refrigerant gas 1a flows smoothly toward the condensing part 720. As shown in FIG. 31, the refrigerant gas 1a flows into the refrigerant passages 721 through the refrigerant gas distribution passage 23. The refrigerant gas 1a is cooled and condensed while flowing in the X2 direction. The refrigerant liquid 1b condensed in the refrigerant passages 721 merges from the refrigerant passages 721 at the refrigerant liquid collection passage 24 due to the action of gravity.

The refrigerant liquid 1b that has been vaporized and decreased in the passage portions 711 is replenished from the lower end sides of the passage portions 711 through the refrigerant liquid collection passage 24, the inlet-side accommodation portion 772, and the lower connection path 713. In this manner, the refrigerant 1 is circulated in the cooler 700.

The remaining configurations of the seventh embodiment are similar to those of the fifth embodiment.

### Advantageous Effects of Seventh Embodiment

According to the seventh embodiment, similarly to the first embodiment, the boiling part 710 includes the accommodation space 11 to accommodate the refrigerant 1, the refrigerant gas outlet 12 connected to the accommodation space 11, and the refrigerant liquid inlet 13 connected to the accommodation space 11, and thus inhibition of movement of the refrigerant liquid 1b by the refrigerant gas 1a can be reduced or prevented. Furthermore, the boiling part 710 includes the first wall 14 to which the heating elements HS are mounted, the second wall 15 facing the first wall 14 via the accommodation space 11 and adjacent to the external passage 722, and the heat conductive portions 19 to connect the first wall 14 to the second wall 15 through the accommodation space 11, and thus even when the external fluid 2 is at a low temperature, a rapid decrease in cooling performance due to an increase in the amount of heat input can be reduced or prevented.

The cooler 700 according to the seventh embodiment includes the condensing part 720 having a structure in which the flat plate-shaped first layers 40 including the refrigerant passages 721 and the flat plate-shaped second layers 50 including the external passages 722 are stacked, the external passages 722 pass through the condensing part 720 in the Z direction, and the boiling part 710 and the first layers 40 (refrigerant passages 721) and the second layers 50 (external passages 722) constituting the condensing part 720 are stacked in the single direction (Y direction). Accordingly, the components of the condensing part 720 can be joined together by brazing the assembly in which the boiling part 710 and the components of the condensing part 720 are stacked when the cooler 700 is manufactured. Therefore, the cooler 700 can be manufactured in a single brazing step.

The remaining advantageous effects of the seventh embodiment are similar to those of the first embodiment.

### Modification

In the present invention, the heating element may be a semiconductor chip such as a CPU or an electronic circuit mounted on an electronic device such as a server.

In the present invention, the heat conductive portion(s) 19 may have a columnar shape (such as a cylindrical shape or a prismatic shape) extending in the Y direction or have a shape extending obliquely in the Z direction and the X direction, for example. Such a heat conductive portion 19 may correspond to neither a partition wall nor a corrugated fin in the accommodation space 11.

The upper end(s) of the heat conductive portion(s) 19 may 19 may be located below the refrigerant gas outlets 12, or the lower end(s) of the heat conductive portion(s) 19 may be located above the refrigerant liquid inlets 13. Alternatively, the heat conductive portion(s) 19 may be divided into a plurality of portions.

In the present invention, only the first mounts 31 may be provided on the outer surface of the first wall 14.

In the present invention, the refrigerant passage 21 may 21 may be a simple hollow passage or a multi-hole tube having a plurality of independent conduits.

In the present invention, the annular peripheral wall 44 may be provided integrally with one or both of the pair of partition plates 43. For example, one partition plate and an annular peripheral wall may be integrated to configure a concave member, the other partition plate may be formed into a flat plate shape, and the concave member and the other partition plate may be integrated by brazing to configure the refrigerant passage 21. Similarly, half of an annular peripheral wall may be formed integrally with one partition plate and the other partition plate to form a concave shape, and peripheral wall portions of both the partition plates may be integrated by brazing to configure the refrigerant passage 21.

The condensing part 20 only needs to have at least one refrigerant passage 21 and at least one external passage 22.

In the present invention, for example, the boiling part 10 and the condensing part 20 may be integrally formed by a so-called additive manufacturing method using a 3D printer, or portions constituting the boiling part 10 and the condensing part 20 may be joined by a method other than brazing such as welding.

For example, when a cylindrical heating element such as a motor is cooled, the outer shape of the cooler may be circular to match the heating element (motor), and the circular axial end face of the motor may be mounted to a circular (or annular) first wall.

The refrigerant gas outlets 12 may open to both the first passage portions 411a (611a) and the second passage portions 411b (611b).

For example, in FIG. 19, two heat conductive portions 19 that partition two first passage portions 411a and a second passage portion 411b at the center in the X direction may be removed, and one wide first passage portion 411a may be formed at the center in the X direction. That is, one first passage portion 411a and two second passage portions 411b arranged on both outer sides of the first passage portion 411a may be provided.

In each of the aforementioned first to fourth embodiments, the external passages passing through the condensing part in the Z direction may be provided. In each of the aforementioned fifth to seventh embodiments, the external passages passing through the condensing part in the X direction may be provided.

In the present invention, the heat conductive portions 19 in each of the aforementioned fourth to seventh embodiments may include a corrugated fin 160 shown in the aforementioned second embodiment (FIG. 11). Even in this case, the corrugated fin 160 includes first portions 161 that contact the first wall 14 and second portions 162 that contact the second wall 15, and thus the interior of the accommodation space 11 is partitioned into a plurality of regions. The plurality of regions can form a plurality of passage portions.

What is claimed is:

1. A boiling cooler comprising:
a boiling part being operable to boil a refrigerant by heat exchange with a heating element; and
a condensing part being operable to condense a refrigerant gas by heat exchange with an external fluid, wherein
the boiling part includes:
an accommodation space to accommodate the refrigerant;
a refrigerant gas outlet connected to the accommodation space;
a refrigerant liquid inlet connected to the accommodation space;
a first wall to which the heating element is mounted;
a second wall facing the first wall via the accommodation space and adjacent to an external passage; and
a heat conductive portion to connect the first wall to the second wall through the accommodation space;
the condensing part includes:
a refrigerant passage communicating with the refrigerant gas outlet and the refrigerant liquid inlet; and
the external passage provided between the refrigerant passage and the boiling part to allow the external fluid to flow therethrough; and
the condensing part is configured to:
receive the refrigerant gas through the refrigerant gas outlet; and
send a condensed refrigerant liquid to the refrigerant liquid inlet.

2. The boiling cooler according to claim 1, wherein the heat conductive portion extends in a direction from the refrigerant liquid inlet toward the refrigerant gas outlet in the accommodation space, and includes a plurality of heat conductive portions in the accommodation space.

3. The boiling cooler according to claim 2, wherein the heat conductive portion includes a partition wall in the accommodation space.

4. The boiling cooler according to claim 2, wherein the heat conductive portion includes a corrugated fin in the accommodation space.

5. The boiling cooler according to claim 1, wherein the heat conductive portion is provided from the refrigerant gas outlet to the refrigerant liquid inlet in the accommodation space.

6. The boiling cooler according to claim 1, wherein
the refrigerant gas outlet is located at an upper portion of the accommodation space;
the refrigerant liquid inlet is located at a lower portion of the accommodation space;
the refrigerant is accommodated in the accommodation space such that a liquid level of the refrigerant liquid is located at a height between the refrigerant gas outlet and the refrigerant liquid inlet in a non-operating state at room temperature with no heat input from the heating element; and
the boiling cooler further comprises, on an outer surface of the first wall, a first mount located below the liquid level in the non-operating state and to which the heating element is mounted, and a second mount located above the liquid level in the non-operating state and to which the heating element is mounted.

7. The boiling cooler according to claim 1, wherein the refrigerant passage includes a partition plate to partition the refrigerant passage from the external passage, a peripheral wall to define an outer periphery of the refrigerant passage, and a corrugated fin integrated with the partition plate and the peripheral wall inside the refrigerant passage.

8. The boiling cooler according to claim 1, wherein
the condensing part has a structure in which a flat plate-shaped first layer including the refrigerant passage and a flat plate-shaped second layer including a connection passage to allow the refrigerant passage and the boiling part to communicate with each other and the external passage are stacked; and
the condensing part is stacked on the second wall of the boiling part and integrated with the boiling part.

9. The boiling cooler according to claim 1, wherein
the heat conductive portion extends in a direction from the refrigerant liquid inlet toward the refrigerant gas outlet in the accommodation space, and is operable to partition the accommodation space into a plurality of passage portions;
the plurality of passage portions include:
a first passage portion arranged at a position overlapping with an arrangement region of the heating element via the first wall and communicating with the refrigerant gas outlet; and
a second passage portion adjacent to the first passage portion and communicating with the refrigerant liquid inlet; and
a lower portion of the first passage portion and a lower portion of the second passage portion communicate with each other.

10. The boiling cooler according to claim 9, wherein the refrigerant liquid inlet is provided at a position not opening to the first passage portion but opening to the second passage portion.

11. The boiling cooler according to claim 1, wherein
the condensing part includes a plurality of the refrigerant passages;
the heat conductive portion extends in a direction from the refrigerant liquid inlet toward the refrigerant gas outlet in the accommodation space, and is operable to partition the accommodation space into a plurality of passage portions; and
the boiling cooler further comprises, in a portion of the accommodation space of the boiling part or in the second wall of the boiling part, a distribution portion to allow the plurality of refrigerant passages and the plurality of passage portions to communicate with each other.
